(19) United States
(12) Patent Application Publication
(10) Pub. No.: US 2022/0333239 A1
(43) Pub. Date: Oct. 20, 2022

(54) TUNABLE AND NON-TUNABLE HEAT SHIELDS TO AFFECT TEMPERATURE DISTRIBUTION PROFILES OF SUBSTRATE SUPPORTS

(71) Applicant: LAM RESEARCH CORPORATION, Fremont, CA (US)

(72) Inventors: Ashish SAURABH, Portland, OR (US); Karl Frederick LEESER, West Linn, OR (US); Xinyi CHEN, Beaverton, OR (US); Mukesh Dhami SINGH, Lucknow (IN); Troy GOMM, Tigard, OR (US); Timothy Scott THOMAS, Wilsonville, OR (US); Curtis W. BAILEY, West Linn, OR (US)

(21) Appl. No.: 17/762,525

(22) PCT Filed: Sep. 24, 2020
(86) PCT No.: PCT/US2020/052387

§ 371 Date: Mar. 22, 2022

Related U.S. Application Data
(60) Provisional application No. 62/951,395, filed on Dec. 20, 2019.
(60) Provisional application No. 62/907,082, filed on Sep. 27, 2019.

(51) Int. Cl. C23C 16/458; H01L 21/67; H01L 21/683; C23C 16/52

(52) U.S. Cl. CPC C23C 16/4583; H01L 21/67103; H01L 21/67248; H01L 21/6831; C23C 16/52

(57) ABSTRACT

A heat shield for a platen of a substrate support includes a body and absorption-reflection-transmission regions. The absorption-reflection-transmission regions are in contact with the body and are configured to at least one of affect or modulate at least a portion of a heat flux pattern between a distal reference surface and the platen. The absorption-reflection-transmission regions include tunable aspects to tune the at least a portion of the heat flux pattern.

### CROSS-REFERENCE TO RELATED APPLICATIONS

This application claims the benefit of U.S. Provisional Application No. 62/907,082, filed on Sep. 27, 2019 and U.S. Provisional Application No. 62/951,395, filed on Dec. 20, 2019. The entire disclosures of the applications referenced above are incorporated herein by reference.

### FIELD

The present disclosure relates to heat shields of substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Examples of substrate treatments include etching, deposition, etc. During processing, the substrate is arranged on a substrate support such as an electrostatic chuck (ESC) or a vacuum chuck and one or more process gases may be introduced into the processing chamber.

The one or more process gases may be delivered by a gas delivery system to the processing chamber. In some systems, the gas delivery system includes a manifold connected to a showerhead that is located in the processing chamber. As an example, during a plasma enhanced chemical vapor deposition (PECVD) process, a substrate may be arranged on an ESC or a vacuum chuck in a substrate processing system and a thin film is deposited on the substrate. Chemical reactions are involved in the process, which occur after creation of a plasma from reacting gases and discharge of radio frequency (RF) alternating current (AC) or direct current (DC).

### SUMMARY

A heat shield for a platen of a substrate support is provided. The heat shield includes a body and absorption-reflection-transmission regions. The absorption-reflection-transmission regions are in contact with the body and configured to affect at least a portion of a heat flux pattern between a distal reference surface and the platen. The absorption-reflection-transmission regions include tunable aspects to tune the at least a portion of the heat flux pattern.

In other features, the absorption-reflection-transmission regions are configured to affect at least a portion of the heat flux pattern between the distal reference surface and the platen. In other features, the body has a modular structure including the absorption-reflection-transmission regions. In other features, one or more of the absorption-reflection-transmission regions includes one or more holes. In other features, one or more of the absorption-reflection-transmission regions include at least one of (i) one or more ridges or (ii) one or more trenches.

In other features, one or more of the absorption-reflection-transmission regions includes at least one of (i) multiple different thicknesses or (ii) layers with different materials. In other features, one or more of the absorption-reflection-transmission regions are implemented as different at least one of overlaid layers or radially adjacent layers. In other features, the absorption-reflection-transmission regions are implemented as segments, which are at least one of adjustable, movable, interchangeable, or replaceable to tune the heat flux pattern.

In other features, the body is configured to attach to a shaft at a location between the platen and the distal reference surface, which is a surface of a process chamber wall or other surface affecting a radiation boundary condition. In other features, one or more of the absorption-reflection-transmission regions are tunable to control azimuthal and radial temperature non-uniformity of at least one of the platen or a substrate.

In other features, the body is configured to attach to a shaft at a location between the platen and the distal reference surface, which is a surface of a process chamber wall. In other features, one or more of the absorption-reflection-transmission regions are tunable to control azimuthal and radial temperature non-uniformity of the platen.

In other features, the absorption-reflection-transmission regions are disposed at different azimuthal or radial locations on the body. In other features, one or more of the absorption-reflection-transmission regions have at least one different shape, size, material, contour, or pattern than another one or more of the absorption-reflection-transmission regions.

In other features, a heat shield for a platen of a substrate support is provided. The heat shield includes a body and absorption-reflection-transmission portions. The absorption-reflection-transmission portions in contact with or disposed as part of the body and configured to affect at least a portion of a heat flux pattern between a distal reference surface and the platen. One or more of the absorption-reflection-transmission portions includes at least one different heat flux altering characteristic than another one or more of the absorption-reflection-transmission portions.

In other features, the absorption-reflection-transmission portions are at least one of discrete portions, layers, or overlaid layers. In other features, the absorption-reflection-transmission portions are at least one radial or azimuthally disposed relative to each other. In other features, the absorption-reflection-transmission portions are at different azimuthal or radial locations on the body.

In other features, one or more of the absorption-reflection-transmission portions includes one or more holes. In other features, one or more of the absorption-reflection-transmission portions include at least one of (i) one or more ridges or (ii) one or more trenches.

In other features, one or more of the absorption-reflection-transmission portions includes at least one of multiple thicknesses or different materials. In other features, one or more of the absorption-reflection-transmission portions are implemented as different at least one of overlaid layers or radially adjacent layers.

In other features, the body is configured to attach to a shaft at a location between the platen and the distal reference surface, which is a surface of a process chamber wall. In other features, the absorption-reflection-transmission portions are set to minimize azimuthal and radial temperature non-uniformity of the platen.

In other features, one or more of the absorption-reflection-transmission portions have at least one different shape, size, material, contour, or pattern than another one or more of the absorption-reflection-transmission portions. In other features, the heat shield further includes a holding clamp including the body. The absorption-reflection-transmission portions are implemented as segments extending radially outward from a sidewall of the body.

In other features, a heat shield for a platen of a substrate support is provided. The heat shield includes a body and absorption-reflection-transmission regions. The absorption-reflection-transmission regions are in contact with the body and configured to at least one of affect or modulate at least a portion of a radiative heat flux transfer pattern between a distal reference surface and the platen. The absorption-reflection-transmission regions include tunable aspects to tune the at least a portion of the radiative heat flux transfer pattern. In other features, a heat shield for a platen of a substrate support is provided. The heat shield includes a body and absorption-reflection-transmission portions. The absorption-reflection-transmission portions are in contact with or disposed as part of the body and configured to at least one of affect or modulate at least a portion of a radiative heat flux transfer pattern between a distal reference surface and the platen. One or more of the absorption-reflection-transmission portions includes at least one different radiative heat flux transfer characteristic than another one or more of the plurality of absorption-reflection-transmission portions.

A heat shield for a platen of a substrate support is provided. The heat shield includes absorption-reflection-transmission segments and a frame. The frame includes: a center opening configured to receive a center shaft of the substrate support; tabs protruding radially inward to engage with slots of the center shaft; and windows configured to be at least partially covered by the absorption-reflection-transmission segments in designated locations. The absorption-reflection-transmission segments are configured to be at least one of disposed in or over the windows and held by the frame. In other features, the absorption-reflection-transmission segments and the frame thermally shield a portion of a process chamber wall from the platen.

In other features, the heat shield includes a frame. The absorption-reflection-transmission regions are implemented as absorption-reflection-transmission segments. The frame includes: a center opening configured to receive a shaft of the substrate support, and windows configured to be at least partially covered by the absorption-reflection-transmission segments in designated locations. The body is implemented as the frame. The absorption-reflection-transmission segments are configured to be at least one of disposed in or over the windows and held by the frame. In other features, the frame is ring-shaped or polygon shaped. In other features, the frame includes tabs, which engage with a hardware component.

In other features, the windows include respective edges. The edges are configured to contact or engage with absorption-reflection-transmission segments in the designated locations.

In other features, the windows include respective ledges. The ledges are configured to hold the absorption-reflection-transmission segments in the designated locations. The absorption-reflection-transmission segments are configured to be disposed in the windows and on the ledges.

In other features, one or more of the absorption-reflection-transmission segments are reflective segments and reflect thermal energy received from the platen back at the platen. In other features, one or more of the absorption-reflection-transmission segments are absorption segments and absorb thermal energy emitted by the platen.

In other features, one or more of the absorption-reflection-transmission segments are transmission segments and permit a portion of thermal energy emitted from the platen to be passed through the one or more of the absorption-reflection-transmission segments to the distal reference surface. In other features, one or more of the absorption-reflection-transmission segments is shaped to vary an affect the one or more of the absorption-reflection-transmission segments has on azimuthal temperature non-uniformity across the platen. In other features, one or more of the absorption-reflection-transmission segments is shaped to vary an affect the one or more of the absorption-reflection-transmission segments has on radial temperature non-uniformity across the platen. In other features, the frame is ring-shaped.

In other features, each of the absorption-reflection-transmission segments is modular and is able to be disposed in multiple locations within the windows. In other features, sizes of at least two of the absorption-reflection-transmission segments are different. In other features, the absorption-reflection-transmission segments are wedge-shaped. In other features, the absorption-reflection-transmission segments are circular-shaped.

In other features, the frame includes a first portion and a second portion. The first portion includes the windows. The second portion includes channels and ridges. The channels reflect thermal energy emitted by the platen back to the platen. In other features, at least one of the absorption-reflection-transmission segments is at least partially transparent. In other features, at least one of the absorption-reflection-transmission segments includes layers.

In other features, the layers include a pair of layers and an intermediate layer. Each of the pair of layers includes sapphire. The intermediate layer is disposed between the pair of layers. The intermediate layer includes ceramic.

In other features, the layers include a pair of layers and an intermediate layer. Each of the pair of layers includes sapphire. The intermediate layer is disposed between the pair of layers. The intermediate layer includes at least one of ceramic, a refractory material or metal.

In other features, the absorption-reflection-transmission segments include keyed sides. The frame includes keyed tabs for engaging with the keyed sides of the absorption-reflection-transmission segments. In other features, the center opening of the frame is configured to receive at least a first portion of a thermal barrier. The frame is configured to be disposed on a second portion of the thermal barrier. In other features, each of the windows has a predetermined number of designated locations for one or more of the absorption-reflection-transmission segments.

In other features, a heat shield assembly is provided and includes the heat shield and a first thermal barrier. In other features, the heat shield assembly includes a second thermal barrier. The heat shield is configured to be disposed on and engage with the first thermal barrier. The first thermal barrier is configured to be disposed on and engage with the second thermal barrier.

In other features, a substrate support is provided and includes the heat shield, the first thermal barrier, the center shaft, and the platen. The first thermal barrier is connected to the center shaft. The heat shield is a first heat shield disposed on the first thermal barrier.

In other features, the substrate support includes: a second thermal barrier connected to the center shaft; and a second heat shield disposed on the second thermal barrier. In other features, a radially innermost edge of the heat shield is not in contact with the center shaft.

In other features, a heat shield for a platen of a substrate support of a substrate processing system is provided. The heat shield includes absorption-reflection-transmission segments and a frame. The frame includes a center opening for a center shaft and multiple windows. The center opening is configured to receive at least a portion of a first thermal barrier. The windows are configured to hold the absorption-reflection-transmission segments in designated locations. The absorption-reflection-transmission segments are configured to be at least one of disposed in or over the windows. The absorption-reflection-transmission segments and the frame thermally separate a portion of a process chamber wall from the platen.

In other features, one or more of the absorption-reflection-transmission segments are shaped to vary an affect the absorption-reflection-transmission segments have on azimuthal temperature non-uniformity across the platen. In other features, one or more of the absorption-reflection-transmission segments are shaped to vary an affect the absorption-reflection-transmission segments have on radial temperature non-uniformity across the platen.

In other features, the absorption-reflection-transmission segments include a first absorption-reflection-transmission segment and a second absorption-reflection-transmission segment. A size of the second absorption-reflection-transmission segment is different than a size of the first absorption-reflection-transmission segment. In other features, the first thermal barrier is hexagonally-shaped.

In other features, the heat shield assembly is provided and includes the heat shield and the first thermal barrier. In other features, the heat shield assembly includes a second thermal barrier configured to be connected to the center shaft. The first thermal barrier is configured to be disposed on the second thermal barrier.

In other features, the center opening is hexagonally-shaped. The at least a portion of the first thermal barrier is hexagonally-shaped and engages with the center opening. The second thermal barrier includes twelve sides. Six of the twelve sides of the second thermal barrier are configured to engage with six sides of the first thermal barrier.

In other features, a heat shield for a platen of a substrate support of a substrate processing system is provided. The heat shield includes a body. The body includes: a center opening for a center shaft, where the center opening is configured to receive at least a portion of a first thermal barrier; a first portion including first channels and first ridges, where the first channels reflect thermal energy emitted by the platen back to the platen; a second portion including second channels and second ridges, where the second channels transmit thermal energy received from the platen to a process chamber wall; and an overlapping portion disposed between the first portion and the second portion. In other features, the body is configured to thermally shield a portion of the process chamber wall from the platen. In other features, the overlapping portion does not include channels.

In other features, a heat shield for a platen of a substrate support is provided. The heat shield includes: absorption-reflection-transmission segments; and a holding clamp. The holding clamp includes: a body configured to connect to a center shaft of a substrate process chamber; and a sidewall with slots. Each of the slots is configured to receive a respective portion of one of the absorption-reflection-transmission segments. The absorption-reflection-transmission segments are cantilevered, such that the absorption-reflection-transmission segments are supported by a first portion of the sidewall located below the absorption-reflection-transmission segments and a second portion of the sidewall located above the absorption-reflection-transmission segments.

In other features, the slots and the absorption-reflection-transmission segments are configured, such that each of the absorption-reflection-transmission segments is able to be held in any one of the slots. In other features, the absorption-reflection-transmission segments are wedge-shaped. In other features, the absorption-reflection-transmission segments include access holes for installing and removing the absorption-reflection-transmission segments to and from the holding clamp. In other features, the absorption-reflection-transmission segments are arranged about the holding clamp to affect the heat flux pattern 360° around the center shaft.

In other features, one or more of the plurality of absorption-reflection-transmission portions includes at least one of (i) one or more holes or (ii) one or more pockets.

In other features, each of the absorption-reflection-transmission segments is vertically offset from an adjacent pair of the absorption-reflection-transmission segments. In other features, the absorption-reflection-transmission segments alternate in vertical position around the holding clamp, such that every other one of the absorption-reflection-transmission segments is in a first vertical position and the other absorption-reflection-transmission segments are in a second vertical position; and the second vertical position is higher than the first vertical position.

In other features, a method of manufacturing a heat shield for a platen of a substrate support is provided. The method includes: designing a first heat shield to provide one or more critical dimensions of a first substrate including setting parameters of the first heat shield to provide predetermined heat flux pattern altering characteristics during use of the first heat shield; fabricating the first heat shield according to the parameters; while using the first heat shield, performing a deposition or etch operation to deposit a layer on or etch a layer of a first substrate; performing a metrology operation to measure the one or more critical dimensions; analyzing data generated as a result of performing the metrology operation; and determining whether to redesign the first heat shield to satisfy first predetermined criteria for the one or more critical dimensions.

In other features, the method further includes, in response to determining to redesign the first heat shield: adjusting the parameters to provide the predetermined heat flux pattern altering characteristics; fabricating a second heat shield according to the adjusted parameters; while using the second heat shield, performing a deposition or etch operation to deposit a layer on or etch a layer of a second substrate; performing a metrology operation to measure the one or more critical dimensions; analyzing data generated as a result of performing the metrology operation; and determining whether to redesign the second heat shield to satisfy the first predetermined criteria for the one or more critical dimensions.

In other features, the method further includes: reconfiguring the first heat shield to fine tune one or more of the parameters to set or improve the one or more critical dimensions; while using the first heat shield, performing a deposition or etch operation to deposit a layer on or etch a layer of a second substrate; performing a metrology operation to measure the one or more critical dimensions; analyzing data generated as a result of performing the metrology operation; and determining whether to redesign the first heat shield to satisfy the first predetermined criteria for the one or more critical dimensions.

In other features, the fine tuning of the one or more parameters of the heat shield includes at least one of determining a number of absorption-reflection-transmission segments to include, determining locations of the absorption-reflection-transmission segments on a body of the heat shield, or determining types of the absorption-reflection-transmission segments.

In other features, the method further includes fabricating a monolithic heat shield based on the fine-tuned one or more parameters. In other features, the method further includes fabricating a monolithic heat shield based on the parameters.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of a substrate processing system including a processing chamber having a heat shield in accordance with an embodiment of the present disclosure;

FIG. 2 is a cross-sectional view of a substrate support including a platen and a heat shield in accordance with an embodiment of the present disclosure;

FIG. 3 is a perspective view of a heat shield and corresponding wedge-shaped absorption-reflection-transmission (ART) segments in accordance with an embodiment of the present disclosure;

FIG. 4 is a top view of another heat shield including ridged reflective segments in accordance with an embodiment of the present disclosure;

FIG. 5 is a top cross-sectional view of a processing chamber including another heat shield having a solid-portion without ART segments and another portion with wedge-shaped heat absorbing segments in accordance with an embodiment of the present disclosure;

FIG. 6 is a top cross-sectional view of a processing chamber including another heat shield having a solid-portion without ART segments and another portion with circular ART segments in accordance with an embodiment of the present disclosure;

FIG. 7 is a top cross-sectional view of a processing chamber including another heat shield having a reflector portion and another portion including circular ART segments in accordance with an embodiment of the present disclosure;

FIG. 8 is a top perspective view of another heat shield having a reflector portion and an emitter portion in accordance with an embodiment of the present disclosure;

FIG. 9 is a bottom perspective view of the heat shield of FIG. 8.

FIG. 10 is a side perspective view of a portion of the heat shield of FIG. 8.

FIG. 11 is a top view of another heat shield including wedge-shaped ART segments of equal sizes and thermal barriers in accordance with an embodiment of the present disclosure;

FIG. 12 is a top view of another heat shield including wedge-shaped ART segments of different sizes and a thermal barrier in accordance with an embodiment of the present disclosure;

FIG. 13 is a top perspective view of a frame and the thermal barriers of the heat shields of FIGS. 11-12.

FIG. 14 is a top perspective view of a first one of the thermal barriers of the heat shields of FIGS. 11-12.

FIG. 15 is a top perspective view of a second one of the thermal barriers of the heat shields of FIGS. 11-12.

FIG. 16 is a top perspective view of a wedge-shaped segment in the form of a plate and having a window in accordance with an embodiment of the present disclosure;

FIG. 17 is a top perspective view of a wedge-shaped segment having an upper surface with varying heights in accordance with an embodiment of the present disclosure;

FIG. 18 is a top perspective view of a wedge-shaped segment having a dual-notched radially inward end in accordance with an embodiment of the present disclosure;

FIG. 19 is a top perspective view of a wedge-shaped segment having a thick hollow body in accordance with an embodiment of the present disclosure;

FIG. 20 is a perspective view of different wedge-shaped segments in accordance with an embodiment of the present disclosure;

FIG. 21 is a perspective view of another heat shield including several of the wedge-shaped segment of FIG. 17;

FIG. 22 is a perspective view of a frame of a heat shield including keyed-tabs for ART segments;

FIG. 23 is a top perspective view of a processing chamber and a segmented heat shield with offset and cantilevered ART segments and a holding clamp instead of a frame in accordance with an embodiment of the present disclosure;

FIG. 24 is a side view of a substrate support including a platen and stacked heat shields in accordance with an embodiment of the present disclosure;

FIG. 25 is a side view of an ART segment including multiple layers in accordance with an embodiment of the present disclosure;

FIG. 26 is a side perspective view of a non-tunable heat shield in accordance with another embodiment of the present disclosure;

FIG. 27 is a flow diagram illustrating a method for manufacturing a tunable heat shield in accordance with another embodiment of the present disclosure;

FIG. 28 is a flow diagram illustrating a method for tuning a tunable heat shield in accordance with another embodiment of the present disclosure; and

FIG. 29 is a flow diagram illustrating a method of manufacturing a non-tunable heat shield in accordance with another embodiment of the present disclosure.

In the drawings, reference numbers may be reused to identify similar and/or identical elements.

### DETAILED DESCRIPTION

During a PECVD process, a platen of a substrate support (sometimes referred to as a pedestal or susceptor) is heated via one or more internal heating elements. Temperatures of a substrate support can be of the order of 1000° C. There is a large temperature differential between the substrate support and a processing chamber wall. As an example, a chamber wall may be at 75° C. or lower. As a result, there is a large amount of heat (or energy) loss from the substrate support to the chamber wall and/or other components within the processing chamber that are at cooler temperatures than the substrate support.

For a PECVD process, there are many film properties that are sensitive to temperature and corresponding performance parameters of the substrate (wafer) ace constantly monitored and/or evaluated. In certain applications, stringent requirements can be placed on uniformity of performance parameters within a wafer and wafer-to-wafer. For example, temperatures of the platen can vary depending on: process chamber wall temperatures; amounts of heating of the platen by one or more heating elements in the platen; and substrate processing being performed within the process chamber. A temperature distribution profile across the platen is based on properties of materials of the platen, amounts of heat introduced and absorbed by the platen, and heat lost to the environment including process chamber walls.

Controlling power to heating elements in a platen of a substrate support provides a finite amount of control over a temperature distribution profile of the platen. By controlling heat lost from the platen to surrounding components and environment, temperature modulation of this temperature distribution is able to be better controlled. Temperature modulation refers to the emission of heat from a platen and the reflection of the emitted heat back to the platen, which causes the temperatures across the platen to fluctuate.

The examples set forth herein include tunable and non-tunable heat shields disposed between platens and process chamber walls. The heat shields may be “ring-shaped” and include multiple absorption-reflection-transmission (ART) regions, segments and/or portions with different heat flux pattern altering characteristics, which may be tunable and/or preset to provide selected platen temperature distribution profiles. The ART regions, segments and portions alter heat flux patterns between platens and distal reference surfaces, such as surfaces of a plasma chamber walls.

As used herein, the terms “ART region”, “ART segment” and “ART portion” refer to a heat shield region, segment or portion having corresponding amounts of heat absorption, reflection and transmission characteristics. The ART regions and ART portions of the tunable and non-tunable heat shields may refer to segments, discrete sections, non-discrete sections, radially disposed sections, azimuthally disposed sections, layers, overlaid layers, overlapping layers, etc. Tunable aspects of the heat shields may be used to adjust temperatures of the platens and as a result tune refractive indexes of the platens, which affect temperatures of substrates being processed. The heat shields provide parameters that are preset and/or tunable to control heat loss to an environment of a process chamber including heat loss to components in and/or walls of the process chamber. The ART segments of some of the tunable heat shields provide a segmented modular design that is customizable for various different temperature distribution profiles and corresponding degrees of heat loss. The ART regions, segments and portions are preset and/or tunable to control azimuthal and radial temperature non-uniformity.

The disclosed examples aid in: improving temperature uniformity azimuthally and radially across substrate platens; increasing control over an extent of thermal correction in adjusting temperature distribution profiles; providing hardware fine tuning to compensate for hardware thermal inaccuracies; providing process fine tuning to compensate for process thermal inaccuracies; decreasing the amounts of particles generated during processing by covering potential contaminants and thermally shielding metal parts that can heat up and generate particles; and improving substrate support performance without increasing costs of substrate supports. The disclosed examples also aid in improved thermal response of the heating elements of platens and hence improve productivity. By reducing heat lost, duty cycles of heating elements may be reduced, since not as much energy is needed to provide a same level of heating. Reduced heat loss also allows for use of less costly hardware that is rated for lower levels of heating.

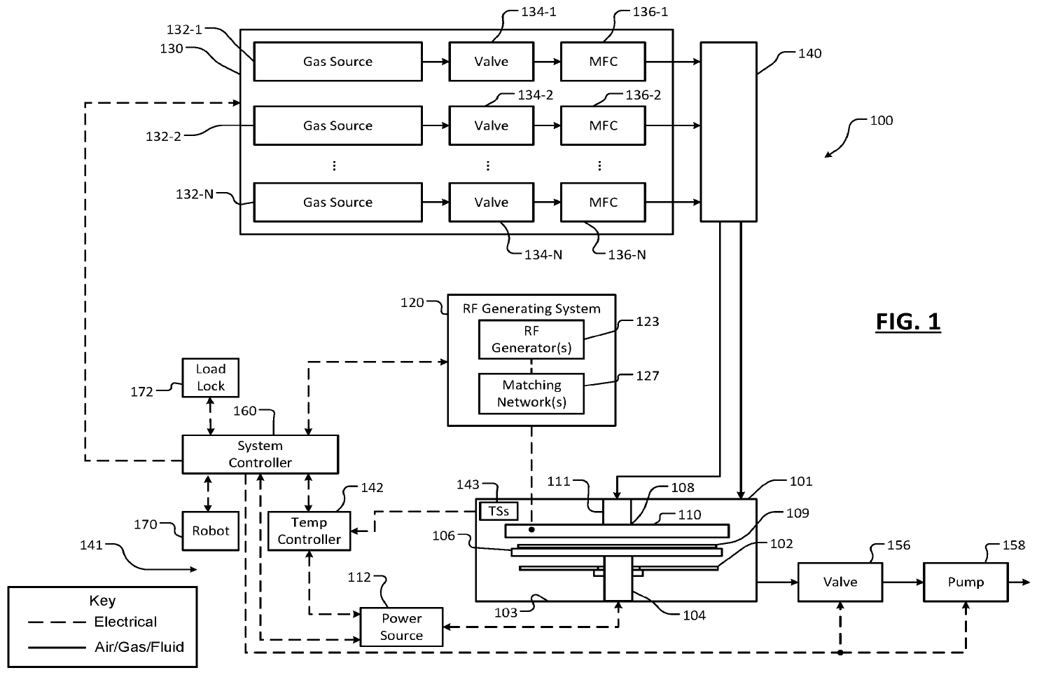

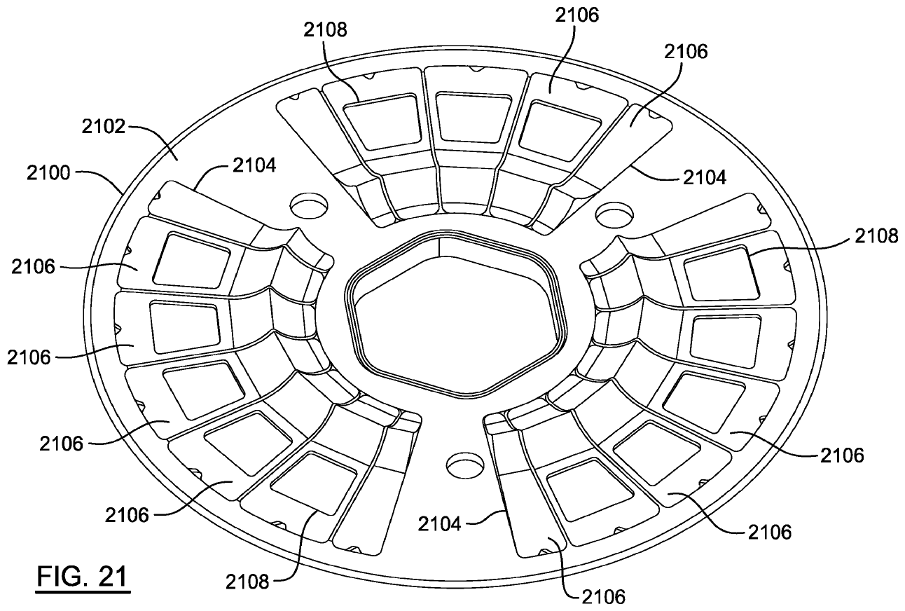

FIG. 1 shows a substrate processing system 100 including a processing chamber 101 having a heat shield 102. The heat shield 102 may be tunable or non-tunable and configured the same or similarly as any of the heat shields disclosed herein. Although a single heat shield is shown, more than one heat shield may be included, as shown in FIG. 21. Although FIG. 1 shows a capacitive coupled plasma (CCP) system, the embodiments disclosed herein are applicable to other plasma processing systems. The embodiments are applicable to plasma enhanced chemical vapor deposition (PECVD) processes.

The substrate processing system 100 includes a substrate support 104, such as an electrostatic chuck or a vacuum chuck, which that is disposed in the processing chamber 101 and includes a platen 106. The substrate support 104 and other substrate supports disclosed herein may be referred to as pedestals or susceptors. The processing chamber 101 has at least one distal reference surface (e.g., distal reference surface 103) opposite the heat shield 102. Other components, such as an upper electrode 108, may be disposed in the processing chamber 101. During operation, a substrate 109 is arranged on and electrostatically or vacuum clamped to the platen 106 of the substrate support 104 and RF plasma is generated within the processing chamber 101.

For example only, the upper electrode 108 may include a showerhead 110 that introduces and distributes gases. The showerhead 110 may include a stem portion 111 including one end connected to a top surface of the processing chamber 101. The showerhead 110 is generally cylindrical and extends radially outward from an opposite end of the stem portion 111 at a location that is spaced from the top surface of the processing chamber 101. A substrate-facing surface or the showerhead 110 includes holes through which process or purge gas flows. Alternately, the upper electrode 108 may include a conducting plate and the gases may be introduced in another manner. The platen 106 may perform as a lower electrode.

The platen 106 may include temperature control elements (TCEs), which may receive power from power source 112. An RF generating system 120 generates and outputs RF voltages to the upper electrode 108. The RF generating system 120 may generate and output RF voltages to the substrate support 104. One of the upper electrode 108 and the substrate support 104 may be DC grounded, AC grounded or at a floating potential. For example only, the RF generating system 120 may include one or more RF generators 123 (e.g., a capacitive coupled plasma RF power generator and/or other RF power generator) that generate RF voltages, which are fed by one or more matching networks 127 to the upper electrode 108. The RF generators 123 may be high-power RF generators producing, for example, 6-10 kilo-watts (kW) of power or more.

A gas delivery system 130 includes one or more gas sources 132-1, 132-2, . . . , and 132-N (collectively gas sources 132), where N is an integer greater than zero. The gas sources 132 supply one or more precursors and gas mixtures thereof. The gas sources 132 may also supply etch gas, carrier gas and/or purge gas. Vaporized precursor may also be used. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. An output of the manifold 140 is fed to the processing chamber 101. For example only, the output of the manifold 140 is fed to the showerhead 110.

The substrate processing system 100 further includes a heating system 141 that includes a temperature controller 142, which may be connected to the TCEs via the power source 112. Although shown separately from a system controller 160, the temperature controller 142 may be implemented as part of the system controller 160. The platen 106 may include multiple temperature controlled zones (e.g., 4 zones, where each of the zones includes 4 temperature sensors).

The temperature controller 142 may control operation and thus temperatures of the TCEs to control temperatures of the platen 106 and a substrate (e.g., the substrate 109). The temperature controller 142 and/or the system controller 160 may control current supplied to the TCEs based on detected parameters from sensors 143 within the processing chamber 205. The temperature sensors 243 may include resistive temperature devices, thermocouples, digital temperature sensors, and/or other suitable temperature sensors. During a deposition process, the platen 106 may be heated up to a predetermined temperature (e.g., 650 degrees Celsius (° C.)).

A valve 156 and pump 158 may be used to evacuate reactants from the processing chamber 101. The system controller 160 may control components of the substrate processing system 100 including controlling supplied RF power levels, pressures and flow rates of supplied gases, RF matching, etc. The system controller 160 controls states of the valve 156 and the pump 158. A robot 170 may be used to deliver substrates onto, and remove substrates from, the substrate support 104. For example, the robot 170 may transfer substrates between the substrate support 104 and a load lock 172. The robot 170 may be controlled by the system controller 160. The system controller 160 may control operation of the load lock 172.

The power source 112 may provide power, including a high voltage to electrodes in the substrate support 104 to electrostatically clamp the substrate 109 to the platen 106. The power source 112 may be controlled by the system controller 160. The valves, pump, power sources, RF generators, etc. may be referred to as actuators. The TCEs may be referred to as temperature adjusting elements.

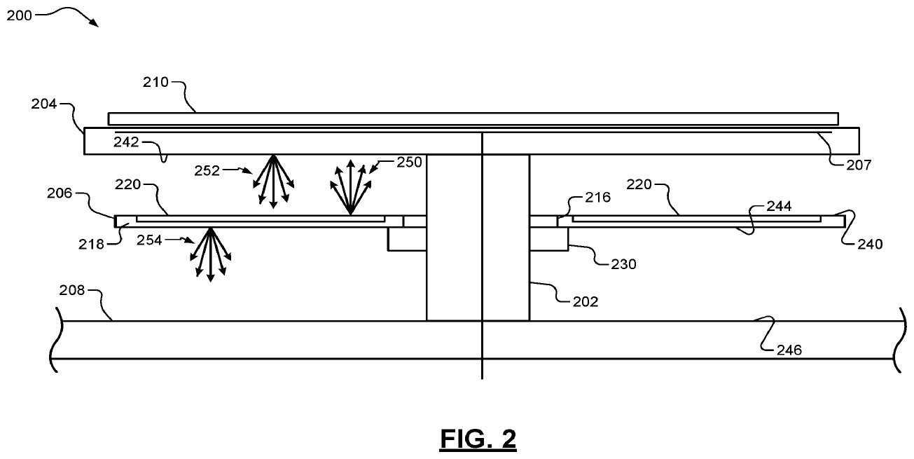

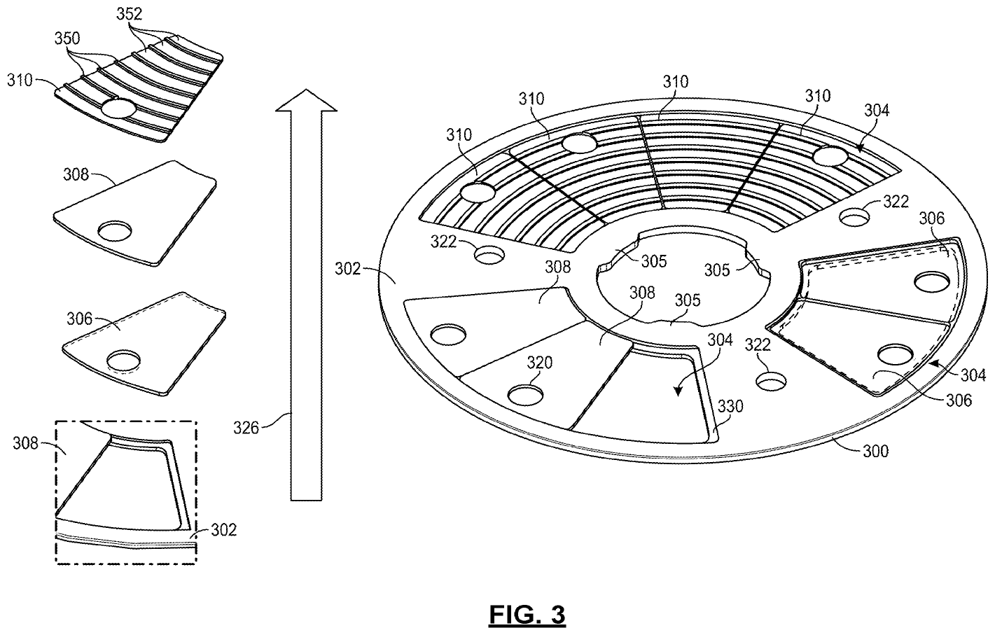

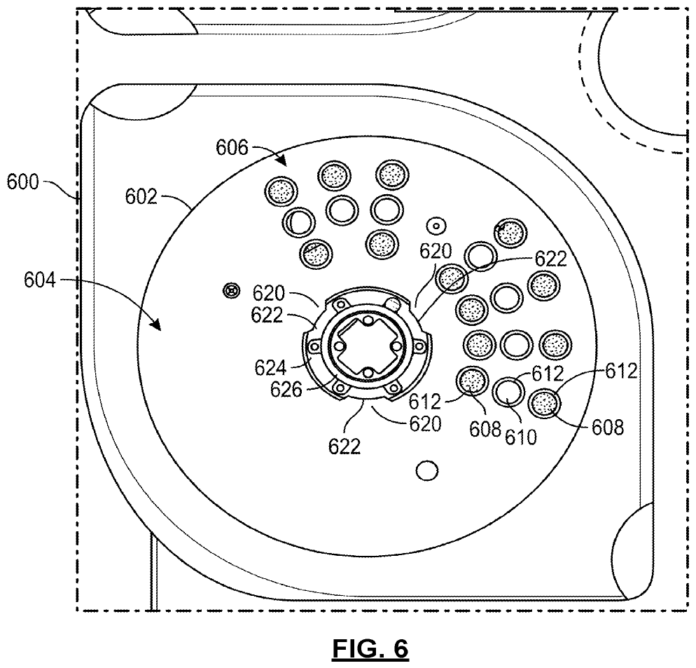

FIG. 2 shows a substrate support 200 that includes a center shaft 202 and a platen 204. A heat shield 206 is tunable and supported on the shaft 202. The heat shield 206 may be replaced with any of the other heat shields disclosed herein. The center shaft 202 may extend up from a process chamber wall 208 and be hollow to allow for power to be provided to one or more heating elements (one heating element 207 is shown) in the platen 204. A substrate 210 is disposed on the platen 204. The heat shield 206 is ring-shaped and has a radially inner opening 216 and a frame 218 and may include ART segments 220 disposed on the frame 218. Examples of the ART segments 220 are shown in FIGS. 3-5, 11 and 15-19. Other ART segments and surfaces are shown in FIGS. 6-10 and 20-21.

The heat shield 206 reduces a temperature gradient between the platen 204 and a next object near the platen 204. For example, without the heat shield 206, the temperature gradient between the platen 204 and the process chamber wall 208 may be 575° C., when the temperature of the platen 204 is 650° C. and the temperature of the process chamber wall is 75° C. With the heat shield 206 and at steady state, the temperature gradient may be reduced to 10-150° C. (or as another example 10-20° C.) when the temperature of the platen 204 is 650° C. and the temperature of the heat shield is 500-640° C. Hence a first difference between a cold zone of the platen 204 and the heat shield and a second difference between a hot zone of the platen 204 and the heat shield may be minimized and a difference between the first difference and the second difference may be minimized and/or insignificant.

The ART segments 220 may be modular and replaceable. The ART segments 220 are set on the frame 218 and held on the frame 218 by gravity. The ART segments, as well as other ART segments disclosed herein, may have different shapes, sizes, angled surfaces, materials, heights, widths, lengths, contours, patterns, etc. The ART segments, as well as other ART segments disclosed herein, may each have multiple layers. The layers may be formed of different materials and may or may not be overlaid on top of each other and/or partially overlap each other. Each of the ART segments 220 has a respective absorption level, reflection level, and transmission level. These characteristics and/or parameters may be set based on a temperature distribution profile and/or a reflective index profile for a platen and given application.

The substrate support 200 may further include one or more thermal barriers (one thermal barrier 230 is shown). The heat shield 206 and the thermal barrier 230 collectively may be referred to as a heat shield assembly. The thermal barrier 230 may be attached to the shaft 202 and support the heat shield 206. The heat shield 206 may rest on the thermal barrier 230. The weight and thickness of the heat shield 206 including the frame 218 and the ART segments 220 may be minimized and balanced, such that the heat shield 206 balances on the thermal barrier 230, where (i) distances between the heat shield 206 and the process chamber wall 208 remain the same, and (distances between the heat shield 206 and the platen 204 remain the same. When balanced, a top surface 240 of the heat shield 206 may be parallel to a bottom surface 242 of the platen 204. Similarly, a bottom surface 244 of the heat shield 206 may be parallel to a top (or distal reference) surface 246 of the process chamber wall 208. In an embodiment, the weight and the thickness of the heat shield 206 are minimized.

Although the heat shield 206 is attached to a shaft at a location between the platen 204 and the distal reference surface 246, the heat shield 206 may alternatively or also be disposed between the platen 204 and one or more other surfaces, which also affect a radiation boundary condition. A thermal energy exchange between any two bodies via radiation is dependent on temperature, emissivity, absorption, reflection and transmission of both bodies and a view factor between the two bodies. Any change in these parameters results in changes in a thermal energy exchange. These parameters may be grouped and referred to as a radiation boundary condition.

Increasing the infrared transmission of the heat shield 206 under a hot zone of the platen 204 increases heat loss from the platen 204. Improving directional emissivity of the heat shield 206 under a cold zone of the platen 204 reduces heat loss, hence if the heat shield 206 is configured to perform as a focusing ring, then infrared radiation may be reflected back to the platen 204. The ART segments 220 may be configured to reflect infrared radiation emitted by the platen 204. Arrows 250 illustrate focused reflection of infrared radiation. Arrows 252 illustrate infrared radiation from the platen 204. Arrows 254 illustrate infrared transmission through the heat shield 206.

The thermal barrier 230 prevents premature failure of the heat shield 206 due to high temperature gradients between the heat shield 206 and the process chamber wall 208. If there is a large temperature gradient, cracking can result in the heat shield 206. The thermal barrier 230 reduces a temperature gradient between the heat shield and a next adjacent object. The thermal barrier 230 is the next adjacent object. This reduction in temperature gradient prevents cracking in the heat shield 206, which increases reliability of the heat shield 206. The thermal barrier 230 and the other thermal barriers disclosed herein may be formed of aluminum oxide (Al₂O₃) and/or aluminum nitride (AlN) and/or any other suitable refractory material and/or suitable metal. In some embodiments, the thermal barrier 230 and the other thermal barriers disclosed herein are formed of insulative materials and perform as thermal insulators.

The ART segments 220 may be configured to adjust (or set) a temperature distribution profile across the platen 204. Examples of the ART segments 220 are shown in FIGS. 3-5, 11-12 and 16-20. FIG. 3 shows a heat shield 300 including a frame 302 with openings (or windows) 304 for ART segments and tabs 305 for engaging with a center shaft. Although the frame 302 is shown having tabs 305 for engaging with the center shaft, the frame 302 may have tabs for engaging with one or more other hardware components. The tabs may extend inward or outward and may be disposed on an inner portion of the frame 302 as shown or may be disposed on other portions of the frame 302. As shown, the ART segments are wedge-shaped and include transparent (or drain) segments 306, solid minimally transparent segments 308 and reflective (non-transparent) segments 310. The ART segments may have different widths to partially or fully cover one or more of the openings 304. One or more of the openings 304 may not include an ART segment.

The frame 302 may have any number of openings for ART segments. During substrate processing, one or more of the openings 304 may not include any ART segments or may be partially filled or fully filled with ART segments. In the example shown, the frame 302 has three openings configured to receive ART segments, one of the openings 304 is fully filled with the segments 306, the second opening is fully filled with the segments 310 and the third opening partially filled with the segments 308.

In a given area of the heat shield 300, a maximum amount of heat transmission from a platen to a process chamber wall is provided when no ART shield is located on the frame between the platen and the process chamber wall. A next reduced amount of heat transmission may be provided when one of the segments 306 is disposed between the platen and the process chamber wall. A maximum amount of heat absorption may be provided when one of the segments 308 is disposed between the platen and the process chamber wall. A maximum amount of thermal energy reflection may be provided when one of the segments 310 is disposed between the platen and the process chamber wall. An arrow 326 is shown to illustrate an amount of thermal impact on the platen of no ART segment, the transparent segments 306, the solid minimally transparent segments 308 and the reflective (non-transparent) segments 310. As an example, the transparent segments 306 may be formed of sapphire and/or other suitable thermally transparent material. The solid minimally transparent segments 308 may be formed of ceramic, zirconium, and/or other suitable minimally transparent and heat absorbing material. The reflective (non-transparent) segments 310 may be formed of aluminum oxide (Al₂O₃), aluminum nitride (AlN), and/or other suitable reflective material.

Each of the ART segments 306, 308, 310 may include removal holes (one hole is designated 320) for grabbing and removing the ART segments 306, 308, 310 with a finger. The frame 302 may have lift pin holes 322 through which lift pins may be passed through and used to lift a substrate off of a platen. The frame 302 also includes in each of the openings 304 a peripheral ledge 330 on which the segments 306, 308, 310 are placed. Although the segments 306, 308, 310 are shown in a particular one of the openings 304, the segments 306, 308, 310 may be moved to other ones of the openings 304. Each of the openings 304 may include different types of ART segments including different types of the segments 306, 308, 310.

The reflective segments 310 include ridges 350 separated by channels 352 having recessed surfaces. The sides of the ridges 350 may be perpendicular to the channels 352 or may be angled to have predetermined pitches to direct reflected heat at predetermined angles and/or to focus heat to particular zones of a platen.

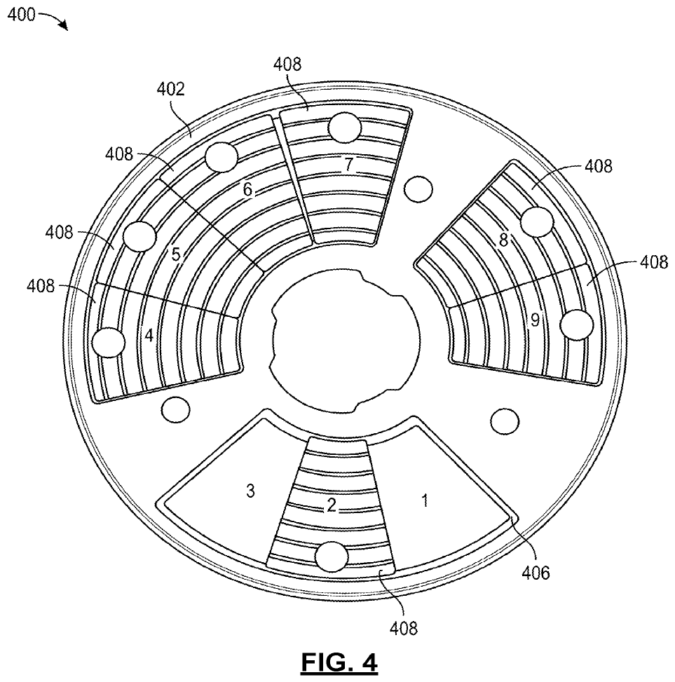

FIG. 4 shows another heat shield 400 including a frame 402 having openings 404 with ledges (one is designated 406) on which ridged reflective segments 408 are disposed. The ridged reflective segments 408 may be wedge-shaped as shown. Available positions of the ridged reflective segments 408 are identified by numbers 1-9. Although 9 positions are shown, the sizes of the ridged reflective segments 408 and the sizes of the openings may be different to accommodate any number of ridged reflective segments.

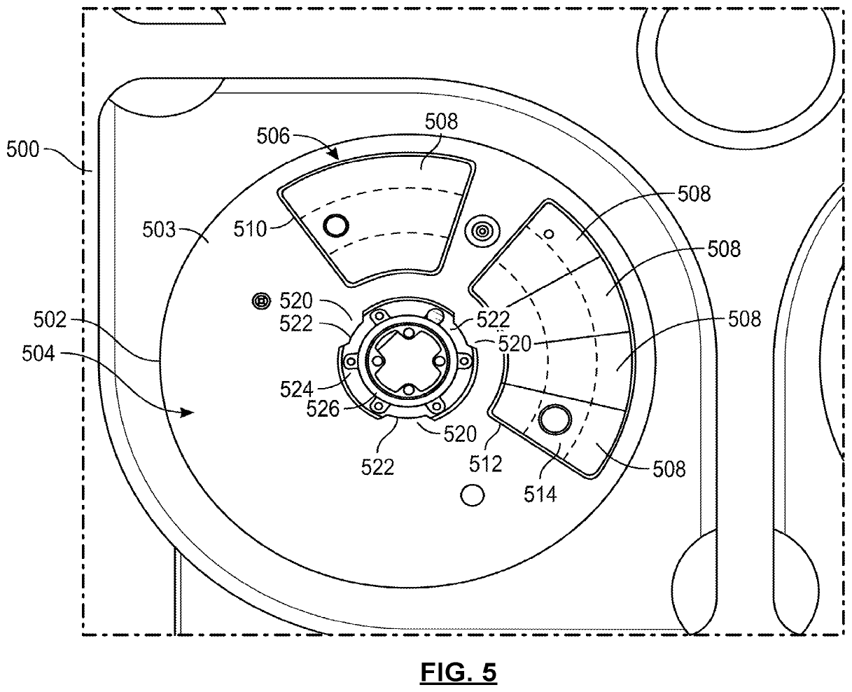

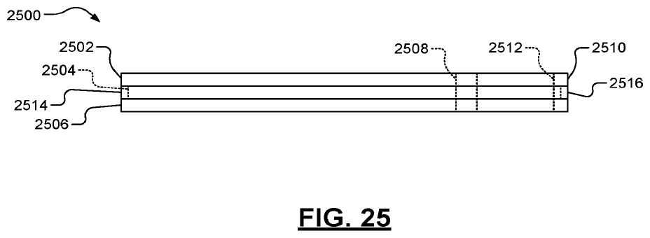

FIG. 5 shows a processing chamber 500 including a heat shield 502. The heat shield 502 includes a frame 503 having a solid (or non-perforated) portion 504 without ART segments and another (or perforated) portion 506 with heat absorbing wedge-shaped segments 508. The heat shield 502 includes two openings 510, 512 in the portion 506. The opening 510 includes a single ART segment. The opening 512 includes four ART segments. Since the ART segments 508 are partially transparent, a ring 514 is visible from a top side of the heat shield 502. In an embodiment, the ART segments 508 are formed of sapphire. In another embodiment, the ART segments 508 include multiple layers, where a silicon (Si) layer is disposed between two sapphire layers. The layers extend parallel to each other and radially and azimuthally. Sapphire material may cover edges of the silicon layer to provide edge protection. The sapphire layers protect the silicon layer from exposure to the environment within the processing chamber 500 and thus prevent degradation of the silicon layer. By including multiple layers, where one or more layers are formed of silicon, the ART segment is more transparent to infrared radiation. An example of a multi-layer ART segment is shown in FIG. 25.

The heat shield 502 includes three tabs 520 that protrude radially inward and slide along slots 522 of a clamp 524. The clamp 524 is on a shaft 526. When installed, the tabs 520 of the heat shield 502 are aligned with the slots 522. The heat shield 502 is then slid onto the clamp 524. The tabs 520 prevent the heat shield 502 from rotating.

FIG. 6 shows a processing chamber 600 including a heat shield 602. The heat shield 602 includes a solid (or non-perforated) portion 604 without ART segments and another (perforated) portion 606 with circular ART segments. A couple of different types of ART segments are shown, some of which are designated 608, 610. The ART segments may be similar to the wedge-shaped segments disclosed herein and are formed of different ART materials, which are selected based on the absorption, reflection and transmission properties selected for a given application. Although the ART segments are shown as being circular, of equal size, and disposed in radially extending rows, the ART segments may have different shapes and sizes and be disposed in different arrangements (or patterns). The ART segments are disposed in respective openings (or windows) 612 and may be on ledges in a similar manner as the wedge-shaped segments.

The heat shield 602 includes three tabs 620 that protrude radially inward and slide along slots 622 of a clamp 624. The clamp 624 is on a shaft 626. When installed, the tabs 620 of the heat shield 602 are aligned with the slots 622. The heat shield 602 is then slid onto the clamp 624. The tabs 620 prevent the heat shield 602 from rotating.

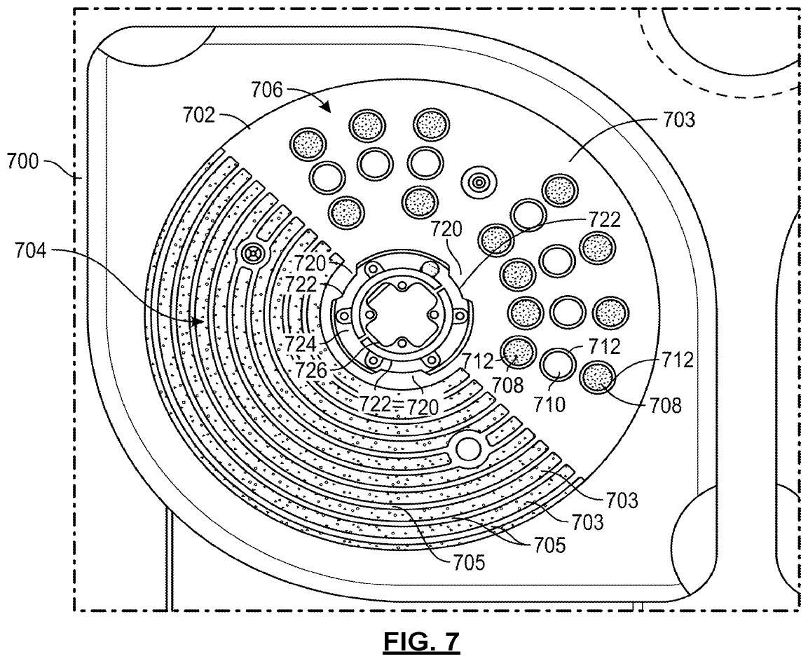

FIG. 7 shows a processing chamber 700 including a heat shield 702 having a reflector portion 704 and another portion 706 including circular ART segments. The reflective portion 704 may be configured similarly as the reflective ART segments disclosed herein and include channels 703 and ridges 705. The channels 703 and/or the reflective portion 704 may be formed of reflective material, such as alumina or other reflective material. The channels 703 may face a bottom side of a substrate platen.

A couple different types of ART segments are shown, some of which are designated 708, 710. The ART segments may be similar to the ART segments of FIG. 6. The ART segments are disposed in respective openings (or windows) 712 and may be on ledges in a similar manner as the wedge-shaped segments disclosed herein.

The heat shield 702 includes three tabs 720 that protrude radially inward and slide along slots 722 of a clamp 724. The clamp 724 is on a shaft 726. When installed, the tabs 720 of the heat shield 702 are aligned with the slots 722. The heat shield 702 is then slid onto the clamp 724. The tabs 720 prevent the heat shield 702 from rotating.

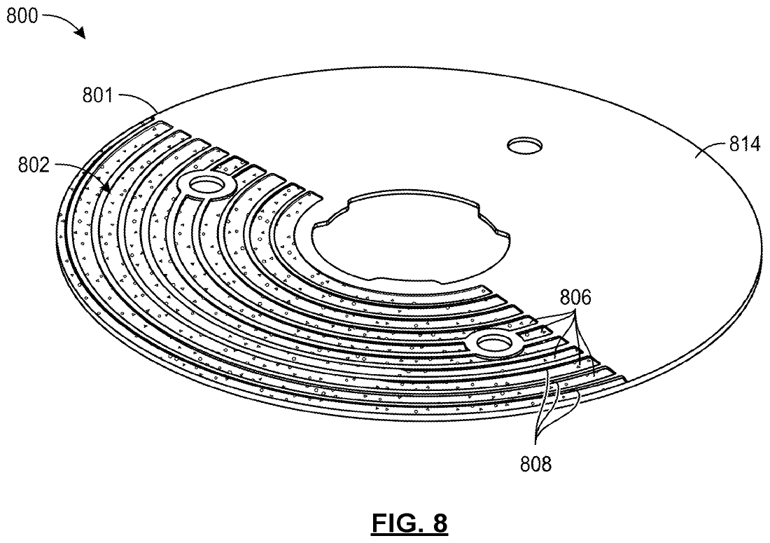

In one embodiment, instead of the heat shield 702 including reflective channels and ridges facing upward toward a bottom surface of a substrate platen, the heat shield 702 includes transmission channels and ridges facing downward towards a process chamber wall. In another embodiment, the heat shield 702 includes both reflective channels and ridges and transmission channels and ridges. Examples of transmission channels and ridges are shown in FIG. 9, which are shown upside down.

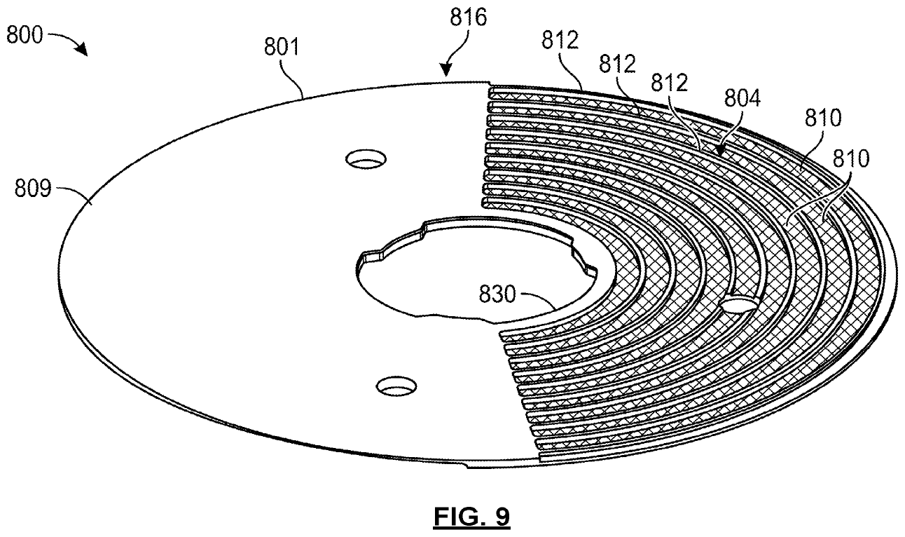

FIGS. 8-10 show a heat shield 800 includes a body (or frame) 801 having a reflector portion (or first half) 802 and an emitter portion (or second half) 804. The reflector portion 802 includes: on a first side, channels 806 with reflective surfaces and ridges 808; and on an opposite side, a solid flat surface 809. The emitter portion 804 includes: on a first side, channels 810 with emissive recessed surfaces and ridges 812; and on an opposite side, a solid flat surface 814. An overlap region 816 may exist between the reflective portion 802 and the emitter portion 804. The channels 806, 810 have side walls, which form the ridges 808, 812. Example side walls 820 are shown in FIG. 10. The heat shield 800 includes three tabs 822 that protrude radially inward and slide along slots of a clamp (e.g., one of the clamps disclosed herein). The heat shield 800 also includes an innermost radial edge 830 and an outermost radial edge 832.

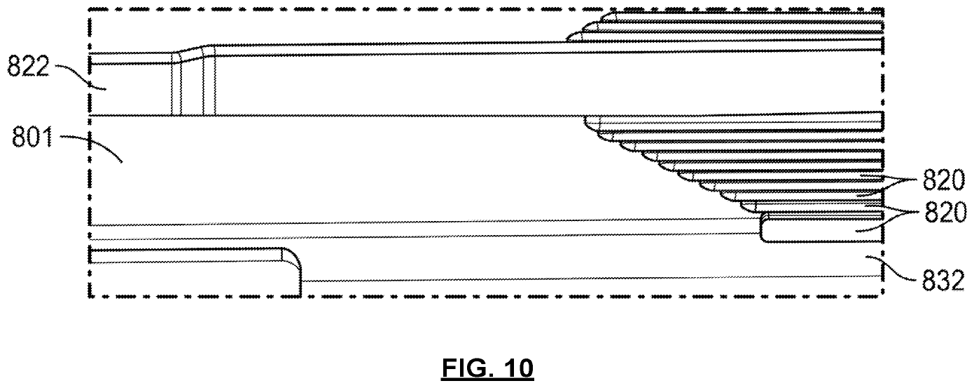

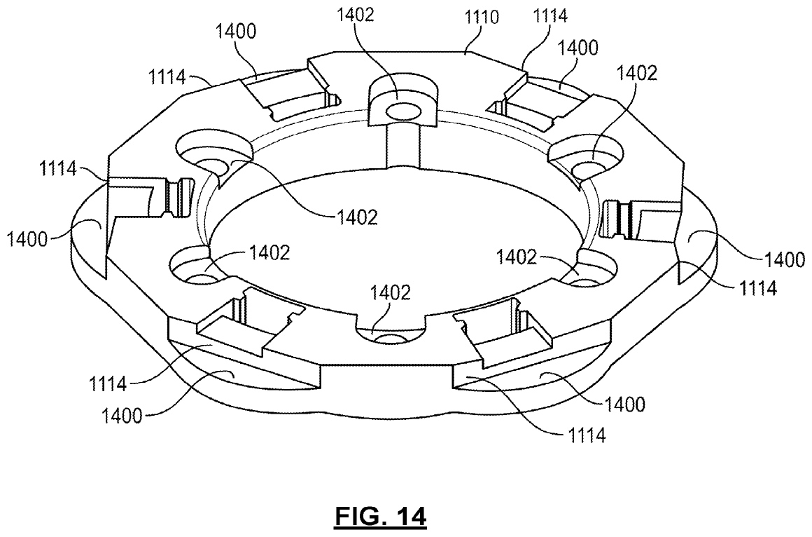

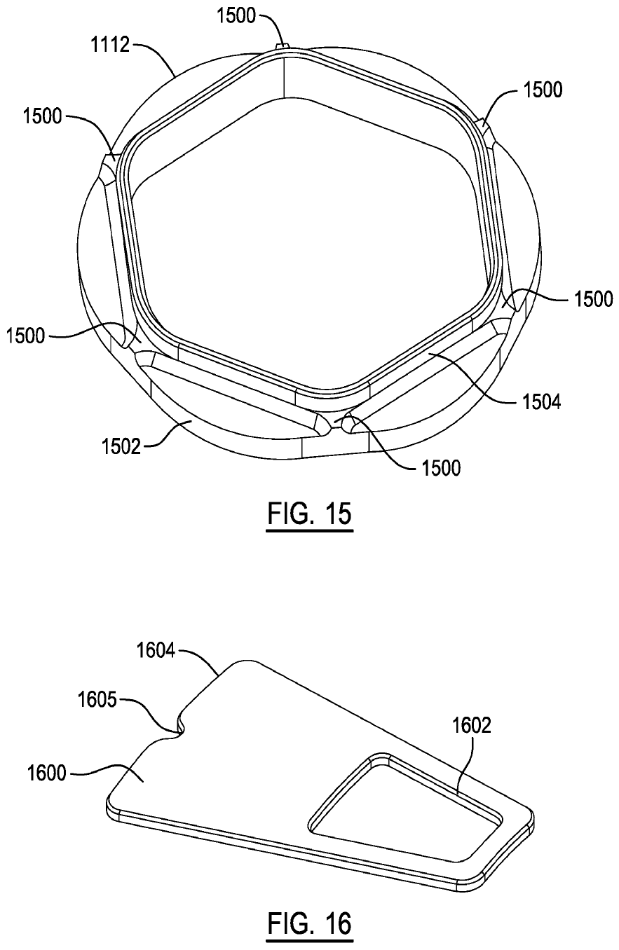

FIG. 11 shows another heat shield 1100 including a frame 1102 having openings 1104 for wedge-shaped ART segments 1106. The ART segments 1106 have equal sizes. The heat shield 1100 is disposed on thermal barriers 1110, 1112. The heat shield 1100 is disposed on and in contact with the thermal barrier 1110. The thermal barrier 1110 is disposed on and in contact with the thermal barrier 1112. During installation, the thermal barrier 1112 may be attached to a center shaft (not shown) followed by the thermal barrier 1110 being slid on the center shaft and rotated to lock with the thermal barrier 1112. The heat shield 1100 is then slid on and rotated to lock with the thermal barrier 1110. Examples of the thermal barriers are further shown and described with respect to FIGS. 14-15. The thermal barriers function in a similar manner as the other thermal barriers disclosed herein.

The thermal barrier 1112 may be hexagonally-shaped and includes 6 points of contact (shown in FIG. 15) for the thermal barrier 1110, or may be any other suitable shape. The thermal barrier 1110 may be dodecagonally-shaped and includes twelve external sides 1114 or may be any other suitable shape. Six of the sides of the thermal barrier 1110 may be in contact with six radially internal sides 1116 of the thermal barrier 1112.

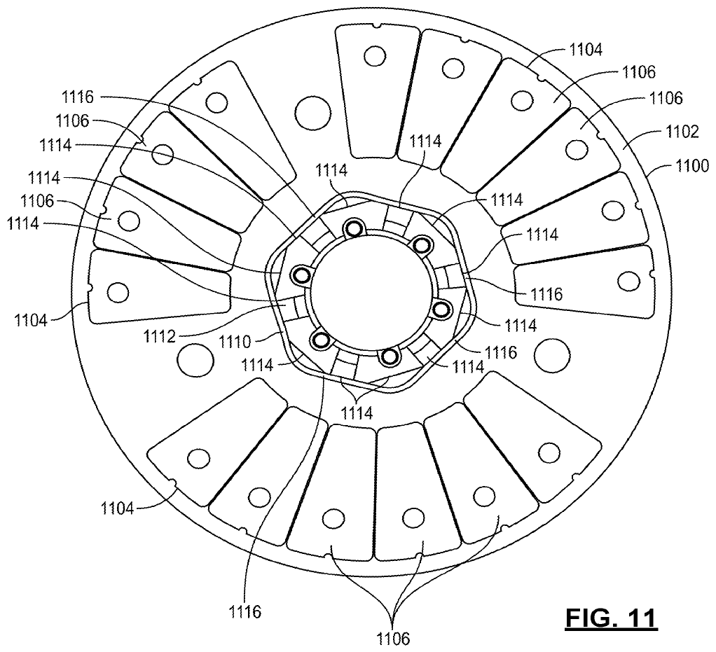

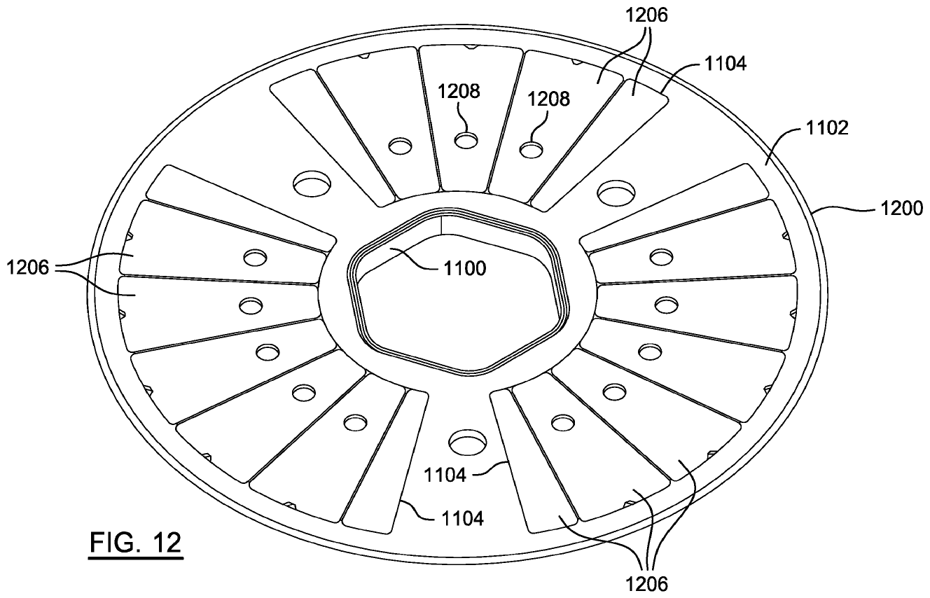

FIG. 12 shows another heat shield 1200 including the frame 1102 having openings 1104 for wedge-shaped ART segments 1206. The ART segments 1206 have different sizes. The ART segments 1206 may have different angular widths to provide a different number of segments in each of the openings 1104. This allows for the level of tuning and/or granularity in temperature control to be adjusted. In the example shown, ART segments of two different sizes are shown. The larger ART segments may have holes 1208 or pockets for easy grabbing, removing and placing of the ART segments. The heat shield 1200 is shown on the thermal barrier 1110.

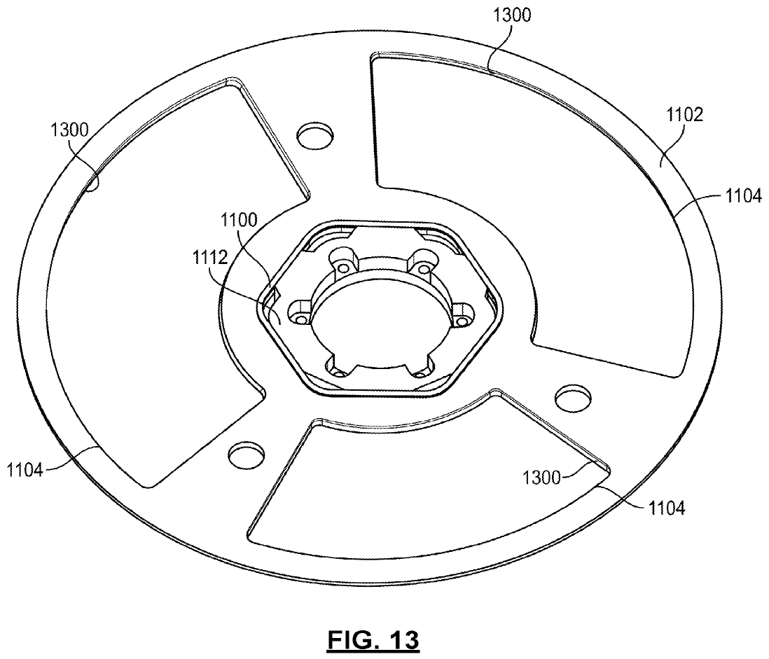

FIG. 13 shows the frame 1102 and the thermal barriers 1110, 1112 of the heat shields 1100, 1200 of FIGS. 11-12. The frame 1102 includes the openings 1104, which have ledges 1300 for ART segments. The ledges 1300 extend around the outer edges of the windows 1104.

Referring now also to FIGS. 14-15. FIG. 14 shows the thermal barrier 1110 of the heat shields 1100, 1200 of FIGS. 11-12. The thermal barrier 1110 provides a barrier-to-heat shield connection. FIG. 15 shows the thermal barrier 1112 of the heat shields 1100, 1112 of FIGS. 11-12. The thermal barrier 1110 provides a shaft-to-barrier connection. The thermal barrier 1110 includes six radially outward protruding tabs 1400 on which the thermal barrier 1112 is set. The tabs 1400 are adjacent the sides 1114. The thermal barrier 1110 includes six attachment points 1402 for attaching the thermal barrier 1110 to a shaft or a fastening member of a shaft.

The thermal barrier 1112 includes the six points of contact (or outward protruding pads 1500 on which one of the heat shields 1100, 1200 is disposed. The thermal barrier 1112 includes a base 1502 and a hexagonally-shaped ring 1504 that extends upward from the base 1502. The base 1502 and the ring 1504 may be formed as a single part. The ring 1504 slides into a center opening of a heat shield and prevents the heat shield from rotating. Sides of the ring 1504 contact a radially innermost edge of the heat shield.

The hexagonally-shaped configuration of the thermal barriers 1110, 1112 and corresponding heat shield frames provide a robust design for better thermal separation. Also, by having the ART segments of the corresponding heat shields have discrete designated locations, performance repeatability is improved.

FIGS. 16-20 show different wedge-shaped ART segments that may be used and or sized to be used in the frames 218, 302, 402, 503, 1102 of FIGS. 2-5 and 11-13. The wedge-shaped ART segments have different geometric shapes that affect azimuthal and radial temperature non-uniformity differently. The geometric shapes and corresponding hole and notch patterns of the wedge-shaped ART segments may be modified and tuned to minimize and/or vary the affects the wedge-shaped ART segments have on azimuthal and/or radial non-uniformity. Also, although the wedge-shaped ART segments are shown having particular shapes and attributes (e.g., holes, notches, pockets, peaks, humps, indentations, etc.), the shapes and attributes may be modified and/or the number of attributes may be altered. FIG. 16 shows a wedge-shaped segment 1600 in the form of a plate and having a window 1602 that is also wedge-shaped.

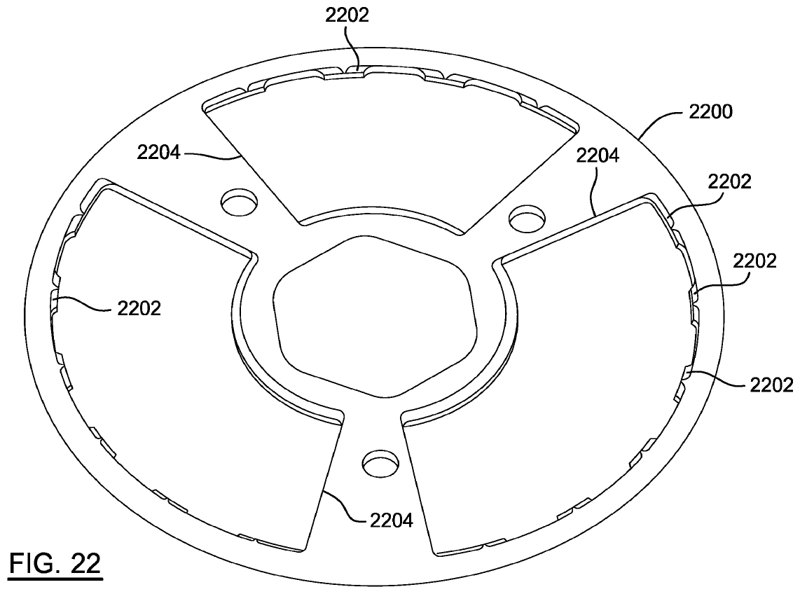

The ART segments disclosed herein may be keyed to aid in the ART segments remaining in a disposed location on a frame of a heat shield. For example, the segment 1600 includes a keyed side 1604 with a notch 1605. Although one side of the segment 1600 is shown as being keyed, more than one side may be keyed. A frame of a heat shield may have keyed-tabs that extend radially inward and couple with the keyed sides of ART segments. An example frame 2200 is shown in FIG. 22 and includes keyed-tabs 2202; one for each ART segment. Although keyed-tabs are shown along radially outermost sides of the windows 2204 of the frame 2200, keyed-tabs may be located on other sides of the windows 2204.

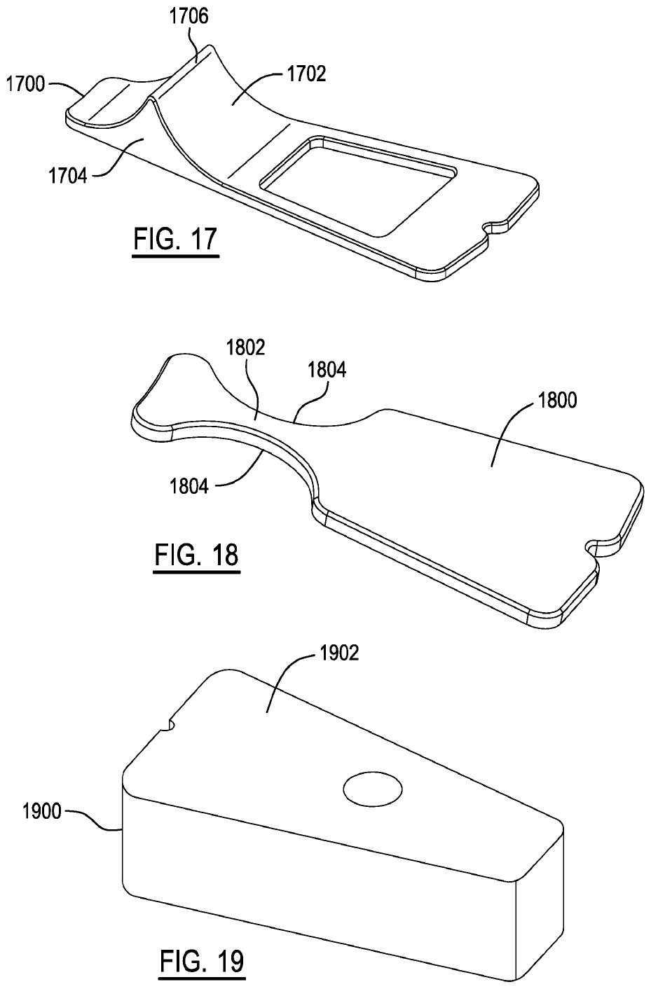

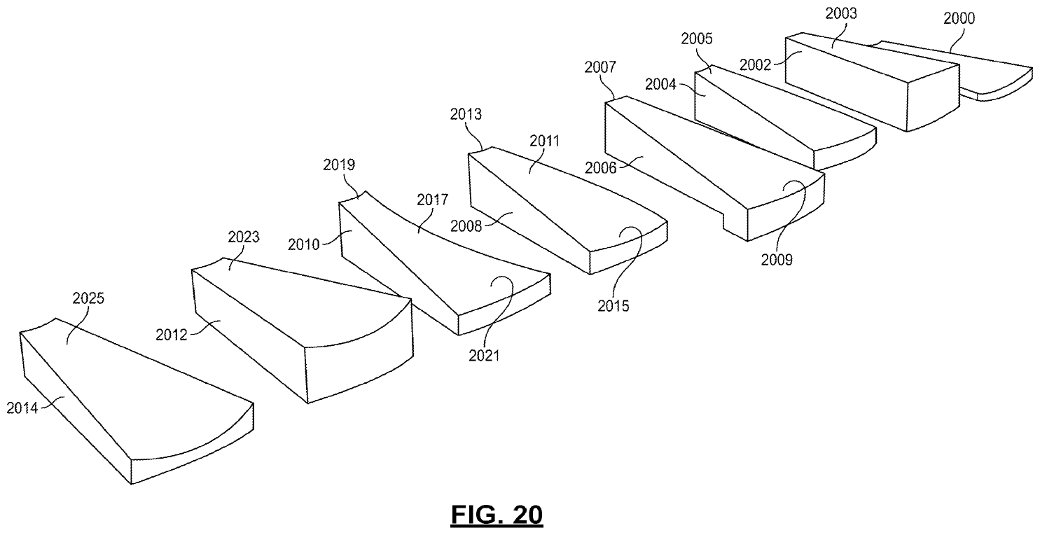

FIG. 17 shows a wedge-shaped segment 1700 having an upper surface 1702 with varying heights with angled sides 1704 and a centrally located peak 1706. As an example, the location of the peak 1706 may be moved radially inward or outward to adjust the variation in affect that the wedge-shaped segment 1700 has on radial temperature non-uniformity. As another example, the height of the peak 1706 relative to a bottom of the wedge-shaped segment 1700 may also be adjusted. An example of a heat shield including several of the wedge-shaped segment 1700 is shown in FIG. 21. FIG. 18 shows a wedge-shaped segment 1800 having a dual-notched radially inward end 1802. The end 1802 includes two notches 1804. FIG. 19 shows a wedge-shaped segment 1900 having a body 1902, which may be hollow to reduce weight. In the example shown, the height of the body 1902 is uniform laterally across the body 1902. Examples of ART segments having varying heights are shown in FIG. 20. The examples of FIGS. 16-18, as well as, at least some of the examples of FIG. 20 may be implemented to affect radial temperature non-uniformity in addition to affecting azimuthal temperature non-uniformity.

FIG. 20 shows: a solid wedge-shaped segment 2000; a thick wedge-shaped segment 2002 having a top surface 2003, which when implemented may be positioned close to a platen; a wedge-shaped segment 2004 with an angled top surface 2005 to direct heat at certain angle relative to platen; a wedge-shaped segment 2006 with an angled top surface 2007 and an extension 2009 that extends beyond and overhangs a radially-outermost edge of a corresponding heat shield; a wedge-shaped segment 2008 that has a top surface 2011, which is radially convex from a radially innermost edge 2013 to a radially outermost edge 2015; a wedge-shaped segment 2010 that has a top surface 2017, which is radially concave from a radially innermost edge 2019 to a radially outermost edge 2021; a wedge-shaped segment 2012 having a concave-shaped top surface 2023 in an azimuthal direction to minimize interaction with neighboring segments with same thickness radially; a wedge-shaped segment 2014 having a concave-cave shaped and angled top surface 2025 in azimuthal direction, such that thickness of the segment is greatest at a radially-innermost edge. The segments 2002, 2004, 2006, 2008, 2010, 2012, and 2014 may be hollow to reduce weight.

The ART segments disclosed herein may be perforated, such that the ART segments include one or more holes. The holes may have different sizes and shapes. Examples of ART segments having a single hole are shown in FIGS. 16-17.

FIG. 21 shows a heat shield 2100 that includes a frame 2102 having windows 2104. Multiple ART segments 2106 are disposed in each of the windows 2104. The ART segments are similar to the ART segment 1700 of FIG. 17 and have different sizes. Some of the ART segments 2106 include an opening 2108 and others do not.

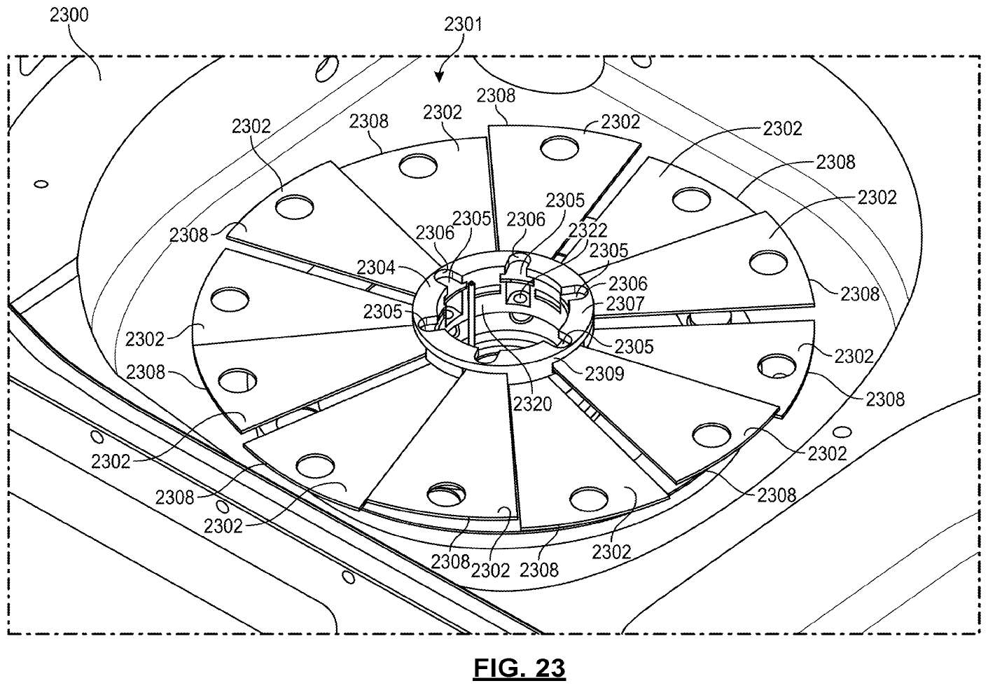

FIG. 23 shows processing chamber 2300 and a segmented heat shield 2301 with offset and cantilevered ART segments 2302 and a holding clamp 2304 instead of a frame. The ART segments 2302 are wedge-shaped and have radially innermost ends 2305 that are inserted into slots 2306 of the holding clamp 2304. The holding clamp 2304 includes a body 2307 having a cylindrically-shaped side wall 2309 with the slots 2306. The radially innermost ends 2305 are inserted into the slots 2306 while the ART segments 2302 are angled downward towards the holding clamp 2304, such that radially outermost ends 2308 of the ART segments 2302 are higher than the radially innermost ends 2305. Once inserted in the slots 2306, the radially outermost ends 2308 of the ART segments are pivoted downward, such that the top surfaces of the ART segments 2302 extend horizontally. In one embodiment, the radially outermost ends 2308 pivoted downward, such that the ART segments 2302 are angled downward, where the radially outermost ends 2308 are 0-0.2° lower than the radially innermost ends 2305. The holding clamp 2304 has a lower portion 2320 with attachment points 2322 for attaching the holding clamp 2304 to a center shaft.

The heat shield 2301 provides a modular design and allows for easy quick replacement of the ART segments 2302 and insertion and removal of the heat shield 2301 without dismantling a substrate support. Each of the ART segments 2302 may be simply pulled out of or inserted into one of the slots 2306 when access to an interior of the chamber 2300 is provided. The ART segments 2302 are disposed 360° around the clamp 2304 and may be offset vertically from each other as shown. This allows for easy inserting and removing of the ART segments 2302. In addition, the offsetting also provides another setting to adjust amounts of absorption, reflection and transmission based on distances between a substrate platen and top surfaces of the ART segments 2302. Although shown as being azimuthally level, each of the ART segments may be azimuthally angled, such that one radially extending edge of the ART segment is lower than the other opposing radially extending edge.

In one embodiment, the ART segments 2302 are formed of ceramic and the clamp 2304 is formed of aluminum. In another embodiment, the ART segments 2302 and the clamp 2304 are formed of aluminum. The ART segments 2302 may be formed of metal based materials other than or in addition to aluminum.

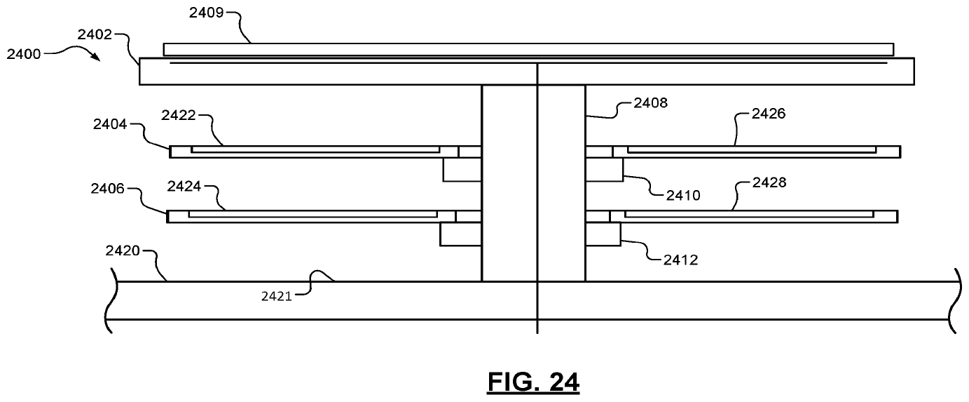

FIG. 24 shows a substrate support 2400 including a platen 2402 and stacked heat shields 2404, 2406 in a nested arrangement. The substrate support 2400 includes a center shaft 2408 on which the platen 2402 is disposed. The platen 2402 supports a substrate 2409. Each of the heat shields 2404, 2406 has a respective thermal barrier 2410, 2412, which are attached to the center shaft 2408 and supports the heat shields 2404, 2406. The heat shields 2404, 2406 and the thermal barriers 2410, 2412 collectively may be referred to as a heat shield assembly. Although two heat shields and two thermal barriers are shown, and number of each may be included. Each additional heat shield provides another layer of thermal energy separation between the platen 2402 and a process chamber wall 2420 having a distal reference surface 2421. Each of the heat shields 2404, 2406 may be configured similarly as any of the heat shields disclosed herein. Also, there may be a gap between the heat shield 2406 and the thermal barrier 2410 as shown or the thermal barrier 2410 may be disposed on the heat shield 2406. The heat shields 2404, 2406 may include ART segments 2422, 2424, 2426, 2428, such as any of the ART segments disclosed herein.

As an example, the platen may be at 650° C., temperatures of the heat shield 2404 may be between 400-500° C., temperatures of the heat shield 2406 may be between 250-350° C., and a temperature of the process chamber wall 2420 may be at 70° C. This nesting arrangement is also applicable to applications, where temperatures of the platen 2402 exceed 650° C.

FIG. 25 shows a multi-layer ART segment 2500 that includes a first layer 2502, a second layer 2504 and a third layer 2506. The ART segment 2500 may include an access hole 2508 and a keyed side 2510 having a notch 2512. The layers 2502 and 2506 may be formed of a first one or more materials and may protect the second layer 2504, which may be formed of a different one or more materials. One of the layers 2502 or 2506 may cover peripheral edges of the second layer, as shown at edges 2514 and 2516. As an example, the layers 2502, 2506 may include sapphire and the intermediate layer 2504 includes at least one of ceramic, a refractory material or one or more metals.

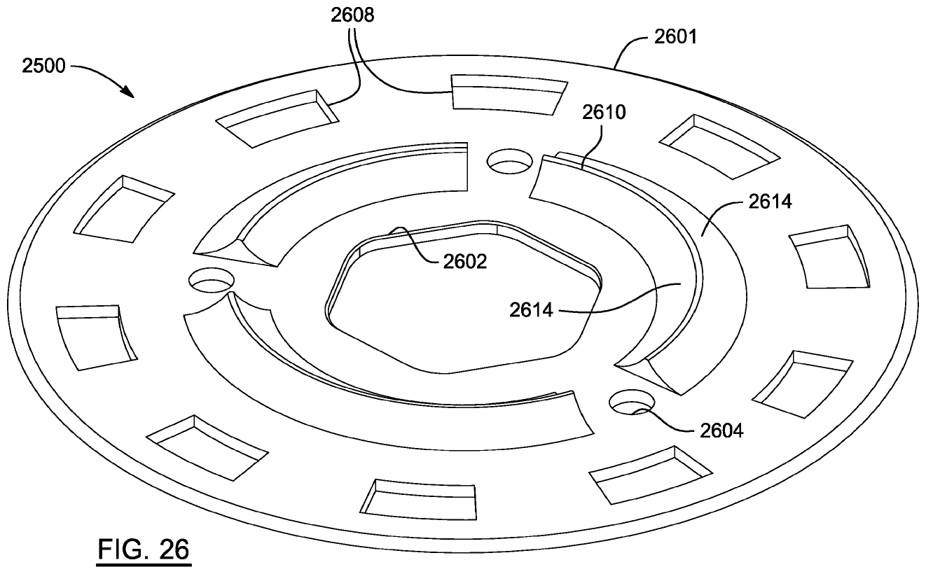

Although several tunable heat shields are describe above, non-tunable heat shields may also be fabricated to have matching ART characteristics of any one of the tunable heat shields in a particular configuration. For example, the tunable heat shields of FIGS. 3-11, 13 and 21-23 may be formed as monolithic structures having corresponding ART regions and/or portions. As an example, a particular configuration of any of the tunable heat shields of FIGS. 3-11, 13 and 21-23 may be selected and then a single monolithic structure may be fabricated having the same size, shapes and dimensions as the selected tunable heat shield. Another example monolithic heat shield is shown in FIG. 26.

FIG. 26 shows a non-tunable heat shield 2600 that is circular-shaped. The heat shield 2600 has a fixed structure including a plate 2601 having a centrally located hexagonally-shaped opening 2602, circular holes 2604, and arced 4-sided holes 2608. Curved ridges 2606 extend away from the plate 2601. The opening is configured to couple a thermal barrier (e.g., the thermal barrier 1110 of FIG. 13). The holes 2604 and the ridges 2606 are located radially outward and surround the opening 2602. The holes 2608 are disposed radially outward of and around the opening 2602, the holes 2604 and the curved ridges 2606. In the example shown, there are three of the holes 2604, three of the ridges 2606 and 10 of the holes 2608, although any number of each may be included. The ridges 2606 include (i) peaks 2610 that extend between longitudinal ends 2612, and (ii) sloped and arched radially opposing sides 2614. The holes 2608 are equal spaced apart from each other.

FIG. 27 shows an iteratively performed method 2700 for manufacturing a tunable or non-tunable heat shield, such as any of the heat shields disclosed herein. The method 2700 includes at 2702 initially designing a heat shield to adjust heat flux pattern altering characteristics by setting and/or improving one or more critical dimensions of a substrate to satisfy first predetermined criteria for the one or more critical dimensions. This includes: determining and/or selecting: sizes, shapes, dimensions, and/or makeup of a frame and/or body; number, sizes, shapes, dimensions and/or makeup of ART regions, segments and/or portions of the frame and/or body; number of ART regions, segments and/or portions to include; sizes, shapes, dimensions, locations and/or makeup of each of the ART regions, segments and/or portions; number, location, sizes shapes and dimensions of holes and/or other features of the heat shield, etc. This also includes fabricating the heat shield to be tested. Operation 2702 may have large recurring costs and long lead times. At 2703, the heat shield is fabricated according to the latest set parameters.

At 2704, the substrate is fed to a station for performing a deposition or a etch operation. At 2706, while using the heat shield, a deposition or etch operation is performed on, for example, a film layer of the substrate to alter the one or more critical dimensions of the substrate.

At 2708, the substrate is transferred from the deposition/etch station to a metrology station. At 2710, metrology is performed to measure the one or more critical dimensions and the measured data is analyzed to determine whether to modify one or more heat flux pattern altering characteristics and/or ART aspects of the heat shield based on the first predetermined criteria. If the design of the heat shield is to be modified, operation 2702 is performed to redesign and fabricate another heat shield. Parameters of the heat shield may be modified based on the analysis and used at operation 2702.

Although the method 2700 is described with respect to forming a tunable heat shield, a similar method may be used to form a non-tunable heat shield.

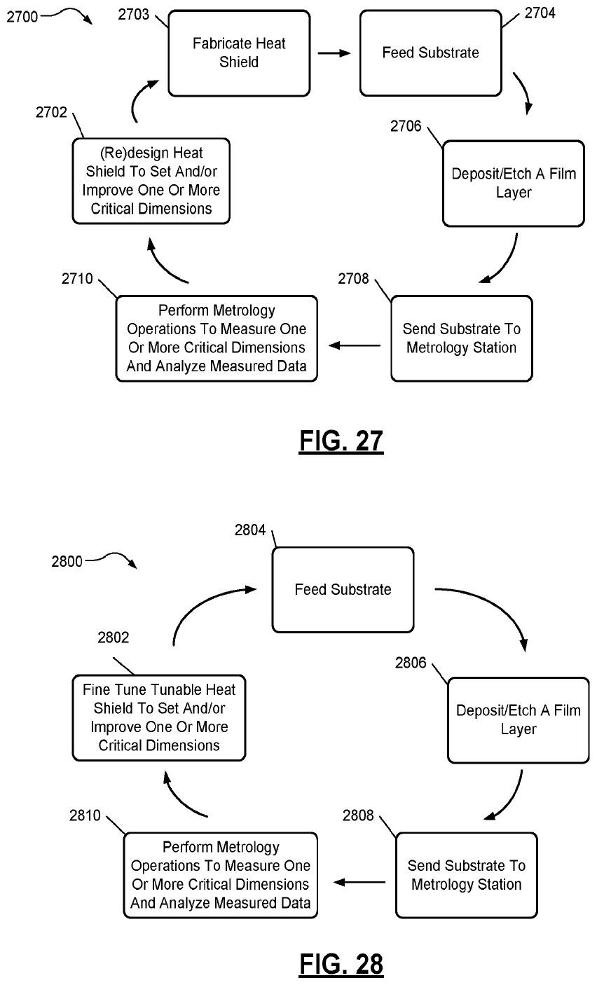

FIG. 28 shows an iteratively performed method 2800 for tuning a tunable heat shield. The method of FIG. 28 may be performed subsequent to completing the method of FIG. 27. The method 2800 includes at 2802 fine tuning the heat shield to set and/or improve one or more critical dimensions of a substrate to satisfy second predetermined criteria. The second predetermined criteria may have more precise requirements than the first predetermined criteria. This may include, for example, determining a number of ART segments to include, the types of the ART segments, and the location of the ART segments on a frame or body of the heat shield. This may include determining where on the frame and/or body not to include an ART segment. Operation 2802 may not have any recurring costs and short lead times, for example, much shorter than the lead time of operation 2702 of FIG. 27.

At 2804, the substrate is fed to a station for performing a deposition or a etch operation. At 2806, while using the heat shield, a deposition or etch operation is performed on, for example, a film layer of the substrate to alter the one or more critical dimensions of the substrate.

At 2808, the substrate is transferred from the deposition/etch station to a metrology station. At 2810, metrology is performed to measure the one or more critical dimensions and the measured data is analyzed to determine whether to modify one or more ART aspects of the heat shield. If the design of the heat shield is to be modified, operation 2802 is performed to further fine tune the heat shield. Parameters of the heat shield may be modified based on the analysis and used at operation 2802.

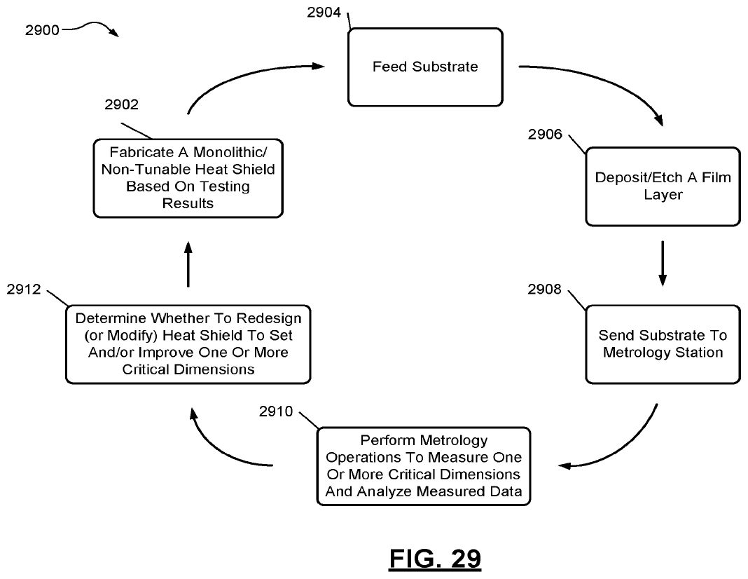

FIG. 29 shows an iteratively performed method 2900 of manufacturing a non-tunable heat shield. This method may be performed alone or subsequent to performing the method of FIG. 28. For example, the method of FIG. 28 may be performed to fine tune a tunable heat shield to save time and costs and then the method of FIG. 29 may be performed to fabricate a monolithic heat shield based on and/or to match the finalized tunable heat shield provided as a result of performing the method of FIG. 28.

The method 2900 includes at 2902 fabricating a monolithic (non-tunable) heat shield. This may be based on previous testing results. Operation 2902 may be performed subsequent to performing one or more of the methods of FIGS. 27 and 28. Operation 2902 may not have any recurring costs and have lead times that are, for example, shorter than the lead time of operation 2702 of FIG. 27 and longer than the lead time of the operation 2802 of FIG. 28.

At 2904, the substrate is fed to a station for performing a deposition or a etch operation. At 2906, while using the heat shield, a deposition or etch operation is performed on, for example, a film layer of the substrate to alter the one or more critical dimensions of the substrate.

At 2908, the substrate is transferred from the deposition/etch station to a metrology station. At 2910, metrology is performed to measure the one or more critical dimensions. At 2912, the measured data is analyzed to determine whether to modify one or more ART aspects of the heat shield and thus redesign and/or modify the heat shield. This may be based on third predetermined criteria. The third predetermined criteria may have more precise requirements than the first predetermined criteria. The third predetermined criteria may match or have similar requirements as the second predetermined criteria. If the design of the heat shield is to be modified, operation 2902 is performed. Parameters of the heat shield may be modified based on the analysis and used at operation 2902.

The disclosed heat shields have parameters that are predetermined and set to modulate heat loss from high-temperature platens. The disclosed heat shields may be used as a tool to improve a design of a process chamber and/or may be used as a feature in a tool to improve tool performance.

The ART segments, regions and portions disclosed herein may not be discrete sections of a heat shield. Multiple tuning techniques may be overlaid atop each other for continuous (in space) tailoring of performance.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from multiple fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A heat shield for a platen of a substrate support, the heat shield comprising:
a body; and
a plurality of absorption-reflection-transmission regions in contact with the body and configured to affect at least a portion of a heat flux pattern between a distal reference surface and the platen, wherein the plurality of absorption-reflection-transmission regions comprise tunable aspects to tune the at least a portion of the heat flux pattern.

2. The heat shield of claim 1, wherein the plurality of absorption-reflection-transmission regions are configured to modulate at least a portion of the heat flux pattern between the distal reference surface and the platen.

3. The heat shield of claim 1, wherein the body has a modular structure including the plurality of absorption-reflection-transmission regions.

4. The heat shield of claim 1, wherein one or more of the plurality of absorption-reflection-transmission regions includes one or more holes.

5. The heat shield of claim 1, wherein one or more of the plurality of absorption-reflection-transmission regions include at least one of (i) one or more ridges or (ii) one or more trenches.

6. The heat shield of claim 1, wherein one or more of the plurality of absorption-reflection-transmission regions comprises at least one of (i) multiple different thicknesses or (ii) layers with different materials.

7. The heat shield of claim 1, wherein one or more of the plurality of absorption-reflection-transmission regions are implemented as different at least one of overlaid layers or radially adjacent layers.

8. The heat shield of claim 1, wherein the body is configured to attach to a shaft at a location between the platen and the distal reference surface, which is a surface of a process chamber wall or other surface affecting a radiation boundary condition.

9. The heat shield of claim 1, wherein one or more of the plurality of absorption-reflection-transmission regions are tunable to control azimuthal and radial temperature non-uniformity of at least one of the platen or a substrate.

10. The heat shield of claim 1, wherein the plurality of absorption-reflection-transmission regions are disposed at different azimuthal or radial locations on the body.

11. The heat shield of claim 1, wherein one or more of the plurality of absorption-reflection-transmission regions have at least one different shape, size, material, contour, or pattern than another one or more of the absorption-reflection-transmission regions.

12. The heat shield of claim 1, wherein the plurality of absorption-reflection-transmission regions are implemented as a plurality of segments, which are at least one of adjustable, movable, interchangeable, or replaceable to tune the heat flux pattern.

13. The heat shield of claim 1, comprising a frame, wherein:
the plurality of absorption-reflection-transmission regions are implemented as a plurality of absorption-reflection-transmission segments;
the frame comprises
a center opening configured to receive a shaft of the substrate support, and
a plurality of windows configured to be at least partially covered by the plurality of absorption-reflection-transmission segments in designated locations;
the body is implemented as the frame; and
the plurality of absorption-reflection-transmission segments are configured to be at least one of disposed in or over the plurality of windows and held by the frame.

14. The heat shield of claim 13, wherein the frame comprises a plurality of tabs, which engage with a hardware component

15. The heat shield of claim 13, wherein the plurality of windows comprise respective edges, wherein the edges are configured to contact or engage with the plurality of absorption-reflection-transmission segments in the designated locations.

16. The heat shield of claim 13, wherein:
the plurality of windows comprise respective ledges, wherein the ledges are configured to hold the plurality of absorption-reflection-transmission segments in the designated locations; and
the plurality of absorption-reflection-transmission segments are configured to be disposed in the plurality of windows and on the ledges.

17. The heat shield of claim 13, wherein one or more of the plurality of absorption-reflection-transmission segments are reflective segments and reflect thermal energy received from the platen back at the platen.

18. The heat shield of claim 13, wherein one or more of the plurality of absorption-reflection-transmission segments are absorption segments and absorb thermal energy emitted by the platen.

19. The heat shield of claim 13, wherein one or more of the plurality of absorption-reflection-transmission segments are transmission segments and permit a portion of thermal energy emitted from the platen to be passed through the one or more of the plurality of absorption-reflection-transmission segments to the distal reference surface.

20. The heat shield of claim 13, wherein one or more of the plurality of absorption-reflection-transmission segments is shaped to vary an affect the one or more of the plurality of absorption-reflection-transmission segments has on azimuthal temperature non-uniformity across the platen.

21. The heat shield of claim 13, wherein one or more of the plurality of absorption-reflection-transmission segments is shaped to vary an affect the one or more of the plurality of absorption-reflection-transmission segments has on radial temperature non-uniformity across the platen.

22. The heat shield of claim 13, wherein the frame is ring-shaped or polygon shaped.

23. The heat shield of claim 13, wherein each of the plurality of absorption-reflection-transmission segments are modular and are able to be disposed in multiple locations within the plurality of windows.

24. The heat shield of claim 13, wherein sizes of at least two of the plurality of absorption-reflection-transmission segments are different.

25. The heat shield of claim 13, wherein the plurality of absorption-reflection-transmission segments are wedge-shaped.

26. The heat shield of claim 13, wherein the plurality of absorption-reflection-transmission segments are circular-shaped.

27. The heat shield of claim 13, wherein:
the frame comprises a first portion and a second portion;
the first portion includes the plurality of windows;
the second portion includes a plurality of channels and a plurality of ridges; and
the plurality of channels reflect thermal energy emitted by the platen back to the platen.

28. The heat shield of claim 13, wherein at least one of the plurality of absorption-reflection-transmission segments is at least partially transparent.

29. The heat shield of claim 13, wherein at least one of the plurality of absorption-reflection-transmission segments comprises a plurality of layers.

30. The heat shield of claim 29, wherein:
the plurality of layers comprise a pair of layers and an intermediate layer;
each of the pair of layers comprises sapphire;
the intermediate layer is disposed between the pair of layers; and
the intermediate layer comprises at least one of ceramic, a refractory material or metal.

31. The heat shield of claim 13, wherein:
the plurality of absorption-reflection-transmission segments include keyed sides; and
the frame includes keyed tabs for engaging with the keyed sides of the plurality of absorption-reflection-transmission segments.

32. The heat shield of claim 13, wherein:
the center opening of the frame is configured to receive at least a first portion of a thermal barrier; and
the frame is configured to be disposed on a second portion of the thermal barrier.

33. The heat shield of claim 13, wherein each of the plurality of windows has a predetermined number of designated locations for one or more of the plurality of absorption-reflection-transmission segments.

34. A heat shield assembly comprising:
the heat shield of claim 13; and
a first thermal barrier.

35. The heat shield assembly of claim 34, further comprising a second thermal barrier, wherein:
the heat shield is configured to be disposed on and engage with the first thermal barrier; and
the first thermal barrier is configured to be disposed on and engage with the second thermal barrier.

36. A substrate support comprising:
the heat shield of claim 34;
the first thermal barrier;
the center shaft; and
the platen,
wherein
the first thermal barrier is connected to the center shaft, and
the heat shield is a first heat shield disposed on the first thermal barrier.

37. The substrate support of claim 36, further comprising:
a second thermal barrier connected to the center shaft; and
a second heat shield disposed on the second thermal barrier.

38. The substrate support of claim 36, wherein a radially innermost edge of the heat shield is not in contact with the center shaft.

39. The heat shield of claim 1, comprising a frame, wherein:
the plurality of absorption-reflection-transmission regions are implemented as a plurality of absorption-reflection-transmission segments;
the frame comprises
a center opening for a center shaft, wherein the center opening is configured to receive at least a portion of a first thermal barrier, and
a plurality of windows configured to hold the plurality of absorption-reflection-transmission segments in designated locations;
the plurality of absorption-reflection-transmission segments are configured to be at least one of disposed in or over the plurality of windows; and
the plurality of absorption-reflection-transmission segments and the frame thermally separate a portion of a process chamber wall from the platen.

40. The heat shield of claim 39, wherein one or more of the plurality of absorption-reflection-transmission segments are shaped to vary an affect the plurality of absorption-reflection-transmission segments have on azimuthal temperature non-uniformity across the platen.

41. The heat shield of claim 39, wherein one or more of the plurality of absorption-reflection-transmission segments are shaped to vary an affect the plurality of absorption-reflection-transmission segments have on radial temperature non-uniformity across the platen.

42. The heat shield of claim 39, wherein:
the plurality of absorption-reflection-transmission segments include a first absorption-reflection-transmission segment and a second absorption-reflection-transmission segment; and
a size of the second absorption-reflection-transmission segment is different than a size of the first absorption-reflection-transmission segment.

43. The heat shield of claim 39, wherein the first thermal barrier is hexagonally-shaped.

44. A heat shield assembly comprising:
the heat shield of claim 39; and
the first thermal barrier.

45. The heat shield assembly of claim 44, further comprising a second thermal barrier configured to be connected to the center shaft,
wherein the first thermal barrier is configured to be disposed on the second thermal barrier.

46. The heat shield assembly of claim 45, wherein:
the center opening is hexagonally-shaped;
the at least a portion of the first thermal barrier is hexagonally-shaped and engages with the center opening;
the second thermal barrier includes twelve sides; and
six of the twelve sides of the second thermal barrier are configured to engage with six sides of the first thermal barrier.

47. The heat shield of claim 1, comprising a holding clamp comprising a sidewall with a plurality of slots, wherein:
the body is configured to connect to a center shaft of a substrate process chamber;
each of the plurality of slots is configured to receive a respective portion of one of the plurality of absorption-reflection-transmission segments;
the plurality of absorption-reflection-transmission regions are implemented as the plurality of absorption-reflection-transmission segments; and
the plurality of absorption-reflection-transmission segments are cantilevered, such that the plurality of absorption-reflection-transmission segments are supported by a first portion of the sidewall located below the plurality of absorption-reflection-transmission segments and a second portion of the sidewall located above the plurality of absorption-reflection-transmission segments.

48. The heat shield of claim 47, wherein the plurality of slots and the plurality of absorption-reflection-transmission segments are configured, such that each of the absorption-reflection-transmission segments is able to be held in any one of the plurality of slots.

49. The heat shield of claim 47, wherein the plurality of absorption-reflection-transmission segments are wedge-shaped.

50. The heat shield of claim 47, wherein the plurality of absorption-reflection-transmission segments include access holes for installing and removing the plurality of absorption-reflection-transmission segments to and from the holding clamp.

51. The heat shield of claim 47, wherein the plurality of absorption-reflection-transmission segments are arranged about the holding clamp to affect the heat flux pattern 360° around the center shaft.

52. The heat shield of claim 47, wherein each of the plurality of absorption-reflection-transmission segments are vertically offset from an adjacent pair of the plurality of absorption-reflection-transmission segments.

53. The heat shield of claim 47, wherein:
the plurality of absorption-reflection-transmission segments alternate in vertical position around the holding clamp, such that every other one of the plurality of absorption-reflection-transmission segments is in a first vertical position and the other absorption-reflection-transmission segments are in a second vertical position; and
the second vertical position is higher than the first vertical position.

54. A heat shield for a platen of a substrate support of a substrate processing system, the heat shield comprising a body, wherein:
the body comprises
a center opening for a center shaft, wherein the center opening is configured to receive at least a portion of a first thermal barrier,
a first portion comprising first channels and first ridges, wherein the first channels reflect thermal energy emitted by the platen back to the platen,
a second portion comprising second channels and second ridges, wherein the second channels transmit thermal energy received from the platen to a process chamber wall, and
an overlapping portion disposed between the first portion and the second portion; and
the body is configured to thermally shield a portion of the process chamber wall from the platen.

55. The heat shield of claim 54, wherein the overlapping portion does not include channels.

56. A heat shield for a platen of a substrate support, the heat shield comprising:
a body; and
a plurality of absorption-reflection-transmission portions in contact with or disposed as part of the body and configured to affect at least a portion of a heat flux pattern between a distal reference surface and the platen, wherein one or more of the plurality of absorption-reflection-transmission portions comprises at least one different heat flux altering characteristic than another one or more of the plurality of absorption-reflection-transmission portions.

57. The heat shield of claim 56, wherein the absorption-reflection-transmission portions are configured to modulate at least a portion of the heat flux pattern between the distal reference surface and the platen.

58. The heat shield of claim 56, wherein the absorption-reflection-transmission portions are at least one of discrete portions, layers, or overlaid layers.

59. The heat shield of claim 56, wherein the absorption-reflection-transmission portions are at least one radial or azimuthally disposed relative to each other.

60. The heat shield of claim 56, wherein the plurality of absorption-reflection-transmission portions are at different azimuthal or radial locations on the body.

61. The heat shield of claim 56, wherein one or more of the plurality of absorption-reflection-transmission portions includes at least one of (i) one or more holes or (ii) one or more pockets.

62. The heat shield of claim 56, wherein one or more of the plurality of absorption-reflection-transmission portions include at least one of (i) one or more ridges or (ii) one or more trenches.

63. The heat shield of claim 56, wherein one or more of the plurality of absorption-reflection-transmission portions includes at least one of multiple thicknesses or different materials.

64. The heat shield of claim 56, wherein one or more of the plurality of absorption-reflection-transmission portions are implemented as different at least one of overlaid layers or radially adjacent layers.

65. The heat shield of claim 56, the body is configured to attach to a shaft at a location between the platen and the distal reference surface, which is a surface of a process chamber wall.

66. The heat shield of claim 56, the plurality of absorption-reflection-transmission portions are set to minimize azimuthal and radial temperature non-uniformity of the platen.

67. The heat shield of claim 56, wherein one or more of the plurality of absorption-reflection-transmission portions have at least one different shape, size, material, contour, or pattern than another one or more of the absorption-reflection-transmission portions.

68. The heat shield of claim 56, further comprising a holding clamp comprising the body,
wherein the plurality of absorption-reflection-transmission portions are implemented as segments extending radially outward from a sidewall of the body.

69. A method of manufacturing a heat shield for a platen of a substrate support, the method comprising:
designing a first heat shield to provide one or more critical dimensions of a first substrate including setting parameters of the first heat shield to provide predetermined heat flux pattern altering characteristics during use of the first heat shield;
fabricating the first heat shield according to the parameters;
while using the first heat shield, performing a deposition or etch operation to deposit a layer on or etch a layer of a first substrate;
performing a metrology operation to measure the one or more critical dimensions;
analyzing data generated as a result of performing the metrology operation; and
determining whether to redesign the first heat shield to satisfy first predetermined criteria for the one or more critical dimensions.

70. The method of claim 69, further comprising, in response to determining to redesign the first heat shield:
adjusting the parameters to provide the predetermined heat flux pattern altering characteristics;
fabricating a second heat shield according to the adjusted parameters;
while using the second heat shield, performing a deposition or etch operation to deposit a layer on or etch a layer of a second substrate;
performing a metrology operation to measure the one or more critical dimensions;
analyzing data generated as a result of performing the metrology operation; and
determining whether to redesign the second heat shield to satisfy the first predetermined criteria for the one or more critical dimensions.

71. The method of claim 69, further comprising:
reconfiguring the first heat shield to fine tune one or more of the parameters to set or improve the one or more critical dimensions;
while using the first heat shield, performing a deposition or etch operation to deposit a layer on or etch a layer of a second substrate;
performing a metrology operation to measure the one or more critical dimensions;
analyzing data generated as a result of performing the metrology operation; and
determining whether to redesign the first heat shield to satisfy the first predetermined criteria for the one or more critical dimensions.

72. The method of claim 71, wherein the fine tuning of the one or more parameters of the heat shield includes at least one of determining a number of absorption-reflection-transmission segments to include, determining locations of the absorption-reflection-transmission segments on a body of the heat shield, or determining types of the absorption-reflection-transmission segments.

73. The method of claim 71, further comprising fabricating a monolithic heat shield based on the fine-tuned one or more parameters.

74. The method of claim 69, further comprising fabricating a monolithic heat shield based on the parameters.
